(19) United States
(12) Patent Application Publication
(10) Pub. No.: US 2005/0083744 A1
(43) Pub. Date: Apr. 21, 2005

(54) Semiconductor memory device with MOS transistors each having a floating gate and a control gate

(76) Inventors: Fumitaka Arai, Yokohama-shi (JP); Yasuhiko Matsunaga, Kawasaki-shi (JP); Makoto Sakuma, Yokohama-shi (JP)

Correspondence Address: FROMMER LAWRENCE & HAUG, 745 FIFTH AVENUE- 10TH FL., NEW YORK, NY, 10151, US

(21) Appl. No.: 10/961,880

(22) Filed: Oct. 8, 2004

(30) Foreign Application Priority Data
Oct. 10, 2003 (JP) 2003-352663

(51) Int. Cl. G11C 11/34

(52) U.S. Cl. 365/202

(57) ABSTRACT

A semiconductor memory device includes a first MOS transistor, a second MOS transistor, and a sidewall insulating film. The first MOS transistor has a stacked gate and a silicide layer formed in a source and on the stacked gate. The second MOS transistor has a stacked gate and a silicide layer formed in a region and on the stacked gate. A drain of the first MOS transistor is connected to a source of the second MOS transistor. The sidewall insulating film is formed on the sidewall of the stacked gate of the first MOS transistor. The film thickness of the sidewall insulating film is greater than ½ of the distance between the stacked gates of the first and second MOS transistors. No silicide layer is formed in the drain of the first MOS transistor and in the source of the second MOS transistor.

### CROSS-REFERENCE TO RELATED APPLICATION

This application is based upon and claims the benefit of priority from the prior Japanese Patent Application No. 2003-352663, filed Oct. 10, 2003, the entire contents of which are incorporated herein by reference.

### BACKGROUND OF THE INVENTION

1. Field of the Invention

This invention relates to a semiconductor memory device. More specifically, this invention relates to a nonvolatile semiconductor memory device with MOS transistors each having a floating gate and a control gate.

2. Description of the Related Art

NOR flash memories and NAND flash memories have been widely used as nonvolatile semiconductor memory devices.

In recent years, a flash memory combining the features of the NOR flash memory and the NAND flash memory has been proposed. This type of flash memory has been disclosed in, for example, Wei-Hua Liu, “A 2-Transistor Source-select (2TS) Flash EEPROM for 1.8-V-Only Application,” Non-Volatile Semiconductor Memory Workshop 4.1, 1997. In a flash memory of this type, each memory cell includes two MOS transistors. In such a memory cell, one MOS transistor functioning as a nonvolatile memory section has a structure including a control gate and a floating gate and is connected to a bit line. The other MOS transistor, which is connected to a source line, is used to select a memory cell. In the conventional flash memory, when a SALICIDE (self-aligned silicidation) structure is used, an unnecessary silicide layer is formed, which results in an insufficient operational reliability.

### BRIEF SUMMARY OF THE INVENTION

A semiconductor memory device according to an aspect of the present invention includes:
a first MOS transistor which has a stacked gate including a first and a second semiconductor layer, and a silicide layer formed in the surface of a source region and on the second semiconductor layer, the second semiconductor layer being formed on the first semiconductor layer with an first inter-gate insulating film interposed therebetween and being connected to the first semiconductor layer electrically;
a second MOS transistor which has a stacked gate including a charge accumulation layer and a control gate formed on the charge accumulation layer with an second inter-gate insulating film interposed therebetween, and a silicide layer formed in the surface of a drain region and on the control gate and which is formed adjacent to the first MOS transistor with its source region connected to a drain region of the first MOS transistor; and
a sidewall insulating film which is formed on the sidewall of the stacked gate of the first MOS transistor, the film thickness of the sidewall insulating film formed on the sidewall facing the source region at the stacked gate of the first MOS transistor being greater than ½ of the distance between the stacked gates of the first and second MOS transistors, and no silicide layer being formed in the drain region of the first MOS transistor and in the source region of the second MOS transistor.

### BRIEF DESCRIPTION OF THE SEVERAL VIEWS OF THE DRAWING

FIG. 1 is a block diagram of a system LSI according to a first embodiment of the present invention;

FIG. 2 is a block diagram of a flash memory according to the first embodiment;

FIG. 3 is a plan view of a memory cell array included in the flash memory according to the first embodiment;

FIG. 4 is a sectional view taken along line 4-4′ of FIG. 3;

FIG. 5 is an enlarged view of FIG. 3;

FIGS. 6 to 10 are sectional views showing a first to a fifth manufacturing step for the system LSI according to the first embodiment;

FIG. 11 is a sectional view of the flash memory;

FIG. 12 is a sectional view of a system LSI according to a first modification of the first embodiment;

FIG. 13 is a sectional view of a system LSI according to a second modification of the first embodiment;

FIG. 14 is a circuit diagram of a memory cell array included in a flash memory according to a second embodiment of the present invention;

FIG. 15 is a plan view of the memory cell array included in the flash memory according to the second embodiment;

FIG. 16 is a sectional view taken along line 16-16′ of FIG. 15;

FIG. 17 is an enlarged view of FIG. 16;

FIG. 18 is a sectional view of a system LSI according to a first modification of the second embodiment;

FIG. 19 is a sectional view of a system LSI according to a second modification of the second embodiment;

FIG. 20 is a graph showing the relationship between the position in the bit line direction and the distance between stacked gates in the flash memory according to the second embodiment;

FIG. 21 is a circuit diagram of a memory cell array included in a flash memory according to a third embodiment of the present invention;

FIG. 22 is a plan view of the memory cell array included in the flash memory according to the third embodiment;

FIG. 23 is a sectional view taken along line 23-23′ of FIG. 22;

FIG. 24 is an enlarged view of FIG. 23;

FIG. 25 is a sectional view of a system LSI according to a first modification of the third embodiment;

FIG. 26 is a sectional view of a system LSI according to a second modification of the third embodiment;

FIG. 27 is a block diagram of a system LSI according to a fourth embodiment of the present invention;

FIGS. 28 and 29 are block diagrams of an IC card including a flash memory according to a fifth embodiment of the present invention;

FIG. 30 shows an IC card including the flash memory of the fifth embodiment and a card holder;

FIG. 31 schematically shows a connection unit into which an IC card including the flash memory of the fifth embodiment or a card holder is inserted;

FIG. 32 schematically shows the connection unit into which an IC card including the flash memory of the fifth embodiment or a card holder is inserted and a computer connected to the connection unit;

FIGS. 33 and 34 are block diagrams of an IC card including the flash memory of the fifth embodiment; and

FIG. 35 is a block diagram of a car-mounted system including a flash memory according to each of the first to fifth embodiments.

### DETAILED DESCRIPTION OF THE INVENTION

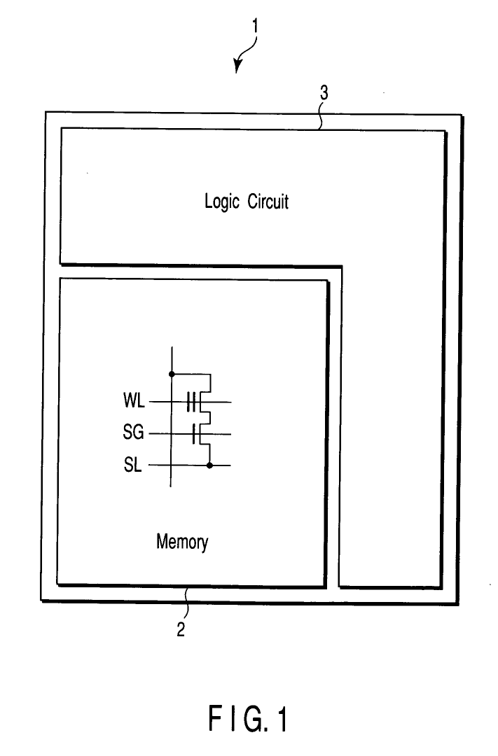

A nonvolatile semiconductor memory device according to a first embodiment of the present invention will be explained by reference to FIG. 1. FIG. 1 is a block diagram of a system LSI according to the first embodiment. An LSI 1 comprises a flash memory 2 and a logic circuit 3.

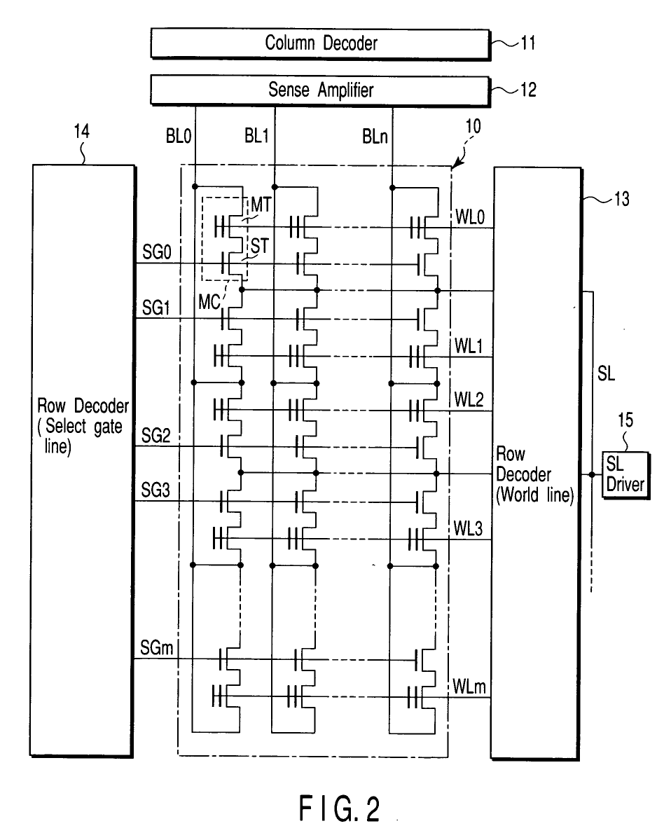

FIG. 2 is a block diagram of the flash memory 2. As shown in FIG. 2, the flash memory 2 includes a memory cell array 10, a column decoder 11, a sense amplifier 12, a first row decoder 13, a second row decoder 14, and a source line driver 15.

The memory cell array 10 has a plurality of ((m+1)×(n+1)) memory cells MCs (m and n are natural numbers) arranged in a matrix. Each of the memory cells MCs includes a memory cell transistor MT and a select transistor ST, which have their current paths connected in series with each other. The memory cell transistor MT has a stacked gate structure that includes a floating gate formed on a semiconductor substrate with a gate insulating film between the gate and the substrate and a control gate formed on the floating gate with an inter-gate insulating film between the control gate and the floating gate. The source region of the memory cell transistor MT is connected to the drain region of the select transistor ST. Memory cells MCs adjoining each other in the column direction share the source region of the select transistor ST or the drain region of the memory cell transistor MT.

The control gates of the memory cell transistors MTs of the memory cells MCs in a same row are connected commonly to any one of word lines WL0 to WLm. The gates of the select transistors STs of the memory cells in a same row are connected commonly to any one of select gate lines SG0 to SGm. The drains of the memory cell transistors MTs of the memory cells MCs in a same column are connected commonly to any one of bit lines BL0 to BLm. The sources of the select transistors STs of the memory cells MCs are connected commonly to a source line SL and then connected to the source line driver 15.

The column decoder 11 decodes a column address signal, thereby producing a column address decode signal. On the basis of the column address decode signal, the column decoder 11 selects any one of bit lines BL0 to BLn.

The first and second row decoders 13, 14 decode a row address signal, thereby producing a row address decode signal. Then, the first row decoder 13 selects any one of word lines WL0 to WLm in a write operation. The second row decoder 14 selects any one of select gate lines SG0 to SGm in a read operation.

The sense amplifier 12 amplifies the data read from the memory cell MC selected by the second row decoder 14 and column decoder 11.

The source line driver 15 supplies a voltage to the source line SL in a read operation.

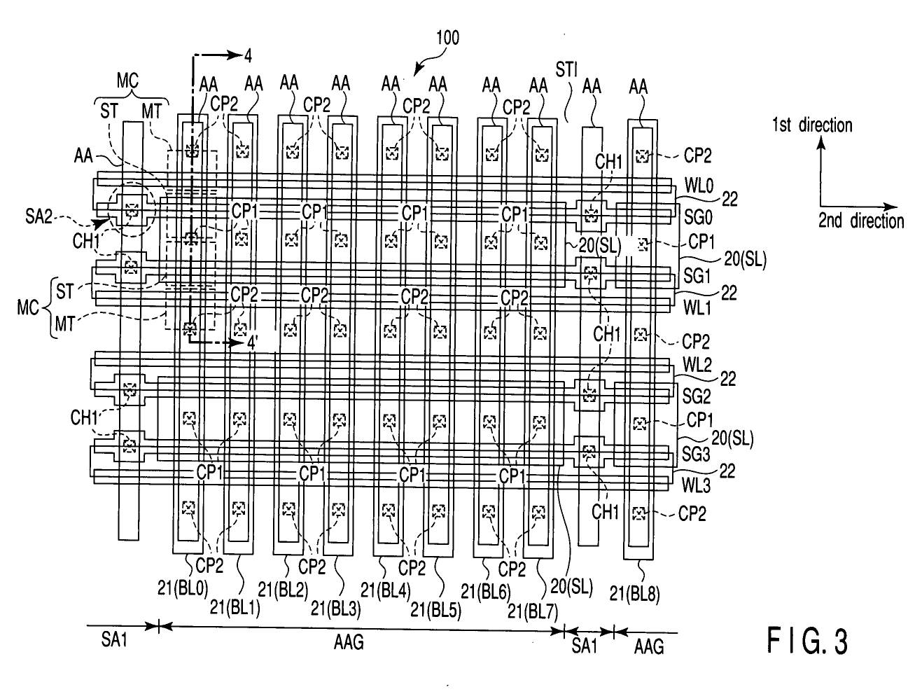

A plane pattern of the memory cell 10 will be explained by reference to FIG. 3. FIG. 3 is a plan view of a part of the memory cell array 10.

As shown in FIG. 3, in the semiconductor substrate. 100, a plurality of stripe shaped element regions AAs extending in a first direction are formed in a second direction perpendicular to the first direction. Stripe shaped word lines WL0 to WLm and select gate lines SG0 to SGm, which extend in the second direction, are formed so as to cross the plurality of element regions AAs. In the regions where the word lines WL0 to WLm cross the element regions AAs, memory cell transistors MTs are formed. In the regions where the select gate lines SG0 to SGm cross the element regions AAs, select transistors STs are formed. Furthermore, in the regions where the word lines WL0 to WLm cross the element regions AAs, floating gates (not shown) isolated on a memory cell transistor MT basis are formed.

As described above, adjoining memory cells MCs have adjoining select gate lines SGs or word lines WLs. Eight columns of element regions AAs are called an element region group AAG. A region where a column of element regions AAs is formed between adjoining element region groups AAGs is called a stitch region SA1. The memory cells MCs formed in an element region group AAG are used to store data. The memory cells MCs in the stitch region SA1 are dummy memory cells, which are not used to store data. In the stitch region SA1, each of the select gate lines SG0 to SGm is formed in such a manner that a part of the select gate line is wider than the remaining part. The wider part is called a shunt region SA2. Each of the select transistors STs has a control gate and a floating gate as does each of the memory cell transistors MTs. The select transistors STs differ from the memory cell transistors MTs in that the floating gates of adjoining select transistors in the second direction are connected to each other. The floating gate and control gate of a select transistor ST are connected to each other in the stitch region SA1 through a contact hole CH1 made in the inter-gate insulating film.

Between adjoining select gate lines SGs (between SG0 and SG1, between SG2 and SG3, . . . ), a stripe shaped metal wiring layer 20 extending in the second direction is formed. The metal wiring layer 20 becomes a part of the source line. The metal wiring layer 20 is divided by the stitch regions SA1 in its longitudinal direction (second direction). That is, the each wiring layer 20 has a independent shape from others with respect to each element region group AA. The metal wiring layer 20 is connected to the source region of the select transistor ST by a contact plug CP1. The individual metal wiring layers 20 are connected to one another in a region (not shown) and then connected to the source line driver 15.

In the element region group AAG, a stripe-shaped metal wiring layer 21 extending in the first direction is formed on the element region AA. The metal wiring layers 21 function as bit lines BL0 to BLn. They are connected to the drain regions of the memory cell transistors MTs by contact plugs CP2.

Furthermore, metal wiring layers 22 are formed into stripe-shaped shapes extending in the second direction. The metal wiring layers 22 are provided for sets of a word line and a select line in a one-to-one correspondence (a set of WL0 and SG1, a set of WL1 and SG1, . . . ). They are connected electrically to the corresponding select gate lines by contact plugs (not shown). Specifically, the individual metal wiring layers 22 function as the shunt lines for select gate lines SG0 to SGm. The metal wiring layer 22 is formed in a region between the central part of the word line WL and the central part of the select gate line SG corresponding to the word line WL. In other words, the metal wiring layer 22 passes through the central part of the memory cell MC. Therefore, the metal wiring layers 22 are arranged at equal intervals in the first direction.

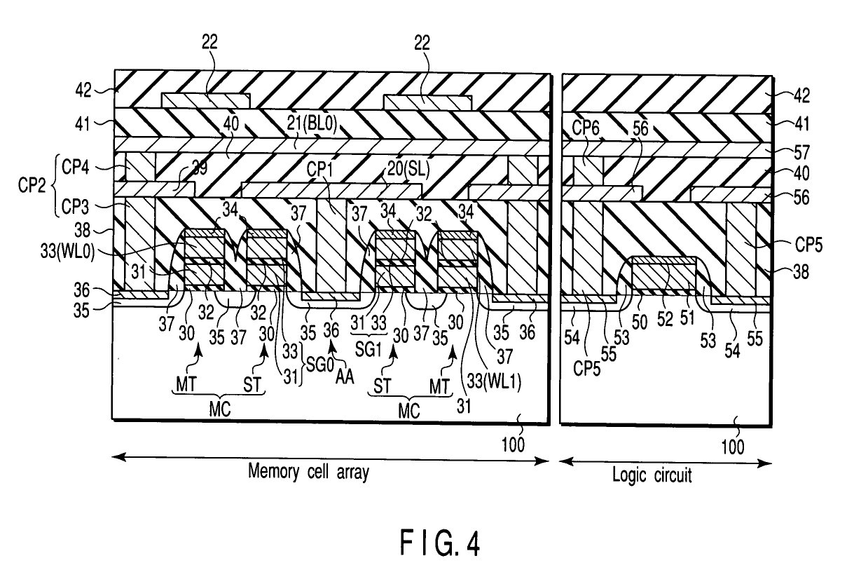

Next, a sectional structure of the flash memory configured as described above will be explained. FIG. 4 is a sectional view taken along line 4-4′ of FIG. 3.

As shown in FIG. 4, a gate insulating film 30 is formed on the element region AA of the semiconductor substrate 100. The gate electrodes of memory cell transistors MTs and select transistors ST are formed on the gate insulating film 30. Each of the gate electrodes of the memory cell transistor MT and select transistor ST includes a polysilicon layer 31 formed on the gate insulating film 30, an inter-gate insulating film 32 formed on the polysilicon layer 31, a polysilicon layer 33 formed on the inter-gate insulating film 32, and a silicide layer 34 formed on the polysilicon layer 33. The inter-gate insulating film 32 is formed of, for example, a silicon oxide film, or an ON film, an NO film, or an ONO film which has a stacked structure of a silicon oxide film and a silicon nitride film. In the memory cell transistor MT, the polysilicon layers 31, which are separated from one another between element regions AAs adjoining in the word line direction, function as floating gates. In addition, the polysilicon layers 33 function as control gates (word lines WLs). The polysilicon layers 33 are connected to each other between element regions AAs adjoining in the word line direction. In the select transistor ST, a part of the inter-gate insulating film 32 is removed in the shunt region and the polysilicon layers 31, 33 are connected electrically. Then, the polysilicon layers 31, 33 function as select gate lines SGs. In the select transistor ST, the polysilicon layer 33 and polysilicon layer 31 are not separated between element regions AAs adjoining in the word line direction and are connected to each other. That is, the floating gates are not separated cell by cell and are all connected to one another in same row.

As described above, memory cells MCs each including a memory cell transistor MT and a select transistor ST are formed so as to meet the following relationship. Adjoining memory cells MCs have their select transistors STs or memory cell transistors MT adjacent to each other. The adjoining select transistors or memory cell transistors share an impurity diffused layer 34. Therefore, two adjoining memory cells MCs, when their select transistors STs adjoin each other, are arranged symmetrically with the impurity diffused layer 34 shared by the two select transistors STs in the center. Conversely, when the memory transistors MTs adjoin each other, they are arranged symmetrically with the impurity diffused layer 34 shared by the two memory cell transistors MTs in the center.

At the surface of the semiconductor substrate 100 located between adjoining gate electrodes, impurity diffused layers 35 functioning as source or drain region are formed. Each impurity diffused layer 35 is shared by adjoining transistors. Specifically, an impurity diffused layer 35 between two adjoining select transistors ST functions as a source region for the two select transistors STs. An impurity diffused layer 35 between two adjoining memory cell transistors MTs functions as a drain region for two memory cell transistors MTs. Moreover, an impurity diffused layer 35 between a memory cell transistor MT and a select transistor ST adjacent to each other functions as the source region of the memory cell transistor MT and the drain region of the select transistor ST. A silicide layer 36 is formed in the surface of the drain of the memory cell transistor MT and in the surface of the source region 35 of the select transistor ST. In the source region 35 of the memory cell transistor MT and in the drain of the select transistor ST, no silicide layer is formed. A sidewall insulating film 37 is formed on the side of the gate electrode (stacked gate) of each of the memory cell transistor MT and select transistor ST. The sidewall insulating film 37 is formed on the side facing the source region 35 of the stacked gate and on the side facing the drain region 35. The region between the stacked gates of the memory cell transistor MT and select transistor ST is filled with the sidewall insulating film 37. Thus, the top of the source region of the memory cell transistor MT and the top of the drain region of the select transistor ST are covered with the sidewall insulating film 37.

An interlayer insulating film 38 is formed on the semiconductor substrate 100 so as to cover the memory cell transistors MTs and select transistors STs. In the interlayer insulating film 38, a contact plug CP1 is formed which reaches the silicide layer 36 formed in the impurity diffused layer (source region) 35 shared by two select transistors ST, ST. A metal wiring layer 20 connected to the contact plug CP1 is formed on the interlayer insulating film 38. The metal wiring layer 20 functions as a source line SL. In the interlayer insulating film 38, a contact plug CP3 is formed which reaches a silicide layer 36 formed in the impurity diffused layer (drain region) shared by two memory cell transistors MT, MT. A metal wiring layer 39 to be connected to the contact plug CP3 is formed on the interlayer insulating film 38.

An interlayer insulating film 40 is formed on the interlayer insulating film 38 so as to cover the metal wiring layers 20, 39. A contact plug CP4 reaching the metal wiring layer 39 is formed in the interlayer insulating film 40. A metal wiring layer 21 connected commonly to a plurality of contact plugs CP4 is formed on the interlayer insulating film 40. The metal wiring layer 21 functions as a bit line BL.

An interlayer insulating film 41 is formed on the interlayer insulating film 40 so as to cover the metal wiring layer 21. A metal wiring layer 22 is formed on the interlayer insulating film 41. The metal wiring layer 22 is connected to the silicide layer 34 of the select transistor ST in the stitch region SA1. An interlayer insulating film 42 is formed on the interlayer insulating film 41 so as to cover the metal wiring layer 22.

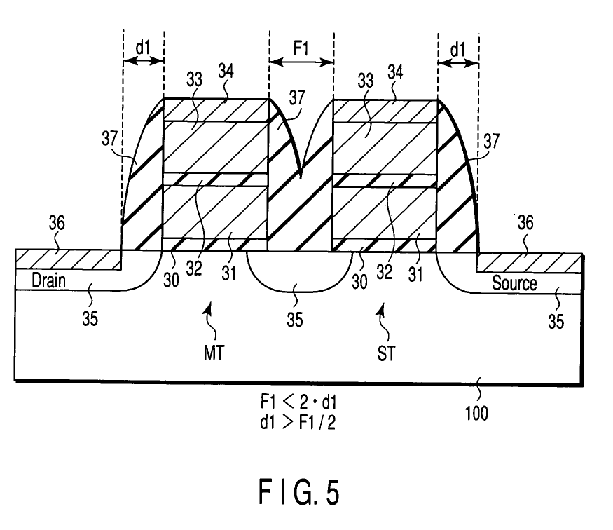

In the memory cell configured as described above, the distance between the gates of the memory cell transistor MT and select transistor ST adjacent to each other and the thickness of the sidewall insulating film 37 have the relationship as shown in FIG. 5. FIG. 5, which is an enlarged view of FIG. 4, is a sectional view of a memory cell. As shown in FIG. 5, if the distance between stacked gates is F1 and the thickness of the sidewall insulating film is d1, they have the following relationship: F1<2·d1. In other words, they satisfy the expression d1>F1/2. A silicide layer 36 is formed in the surface of the drain region 35 of the memory cell transistor MT and in the surface of the source region 35 of the select transistor ST. Therefore, the surface of a part of each of the drain region 35 of the memory cell transistor MT and the source region 35 of the select transistor ST is lower than the surface of the channel region of each of the memory cell transistor MT and the select transistor ST by the film thickness of the silicide layer 36. On the other hand, no silicide layer is formed in the surface of the source region 35 of the memory cell transistor MT and in the surface of the drain region 35 of the select transistor ST. As a result, the surface of the source region 35 of the memory cell transistor MT and the surface of the drain region 35 of the select transistor ST are in the same plane as the surface of the channel region of each of the memory cell transistor MT and the select transistor ST.

Next, the configuration of the logic circuit 3 will be explained by reference to FIG. 4. Explanation will be given, taking a MOS transistor formed in the logic circuit 3 as an example.

As shown in FIG. 4, the gate electrode 51 of a MOS transistor is formed on the element region AA of the semiconductor substrate 100 with a gate insulating film 50 interposed therebetween. Unlike the memory cell transistor MT and select transistor ST, the gate electrode 51 has a single-layer gate structure. A silicide layer 52 is formed on the gate electrode 51. A sidewall insulating film 53 is formed on the sidewall of the gate electrode 51. An impurity diffused layer 54 functioning a source or drain region is formed in the surface of the semiconductor substrate 100. A silicide layer 55 is formed in the surface of the impurity diffused layer 54.

An interlayer insulating film 38 is formed on the semiconductor substrate 100 so as to cover the MOS transistor. A contact plug CP5 reaching the silicide layer 55 is formed in the interlayer insulating film 38. A metal wiring layer 56 to be connected to the contact plug CP5 is formed on the interlayer insulating film 38. An interlayer insulating film 40 is formed on the interlayer insulating film 38 so as to cover the metal wiring layer 56. A contact plug CP6 reaching the metal wiring layer 56 is formed in the interlayer insulating film 40. Then, a metal wiring layer 57 connected to the contact plug CP6 is formed on the interlayer insulating film 40. In addition, interlayer insulating films 41, 42 are formed on the interlayer insulating film 40.

Next, the operation of the flash memory 2 configured as described above will be explained.

<Write Operation>

Data is written simultaneously into all of the memory cells connected to any one of the word lines. Either “0” data or “1” data is written, depending on whether electrons are injected into the floating gate of the memory cell transistor MT. Electrons are injected into the floating gate by Fowler-Nordheim (FN) tunneling.

Hereinafter, the details of a write operation will be explained by reference to FIG. 2.

First, in FIG. 2, writing data (“1” or “0”) is input from an I/O terminal (not shown). Then, the writing data is input to each of the latch circuits (not shown) provided for the bit lines in a one-to-one correspondence. When “1” data is stored in the latch circuit, the latch circuit supplies 0V to the corresponding bit line. Conversely, when “0” data is stored in the latch circuit, the latch circuit supplies VBB (−8V) to the corresponding bit line.

Then, the first row decoder 13 selects any one of the word lines WL0 to WLm. The first row decoder 13 then supplies Vpp (e.g. 12V) to the selected word line. The second row decoder 14 supplies VBB (−8V) to the select gate lines SG0 to SGm. Thus, all of the select transistors STs go into the off state. As a result, the select transistors STs are separated from the source line electrically. The potential of the semiconductor substrate in which the memory cells have been formed is also placed at VBB (−8V).

As a result, the potential corresponding to “1” data or “0” data is applied to the drain region of the memory cell transistor MT via the corresponding one of the bit lines BL0 to BLn. Then, Vpp (12V) is applied to the selected word line WL, 0V is applied to the drain region of the memory cell transistor MT into which “1” data is to be written, and VBB (−8V) is applied to the drain region of the memory cell transistor MT into which “0” data is to be written. Thus, in the memory cell transistor MT into which “1” data is to be written, since the potential difference (12V) between the gate and drain is insufficient, no electron is injected into the floating gate, with the result that the memory cell transistor MT holds the negative threshold value. On the other hand, in the memory cell transistor MT into which “0” data is to be written, since the potential difference (20V) between the gate and drain is large, electrons are injected into the floating gate by FN tunneling. As a result, the threshold value of the memory cell transistor MT changes to positive.

<Read Operation>

In a read operation, data can be read simultaneously from a plurality of memory cells connected to any one of the word lines.

Hereinafter, the details of a read operation will be explained by reference to FIG. 2.

First, in FIG. 2, the second row decoder 14 selects any one of the select gate lines SG0 to SGm. A high level (e.g., Vcc) is supplied to the selected select gate line. All of the unselected select gate lines are at a low level (e.g., 0V). Accordingly, the select transistors STs connected to the selected gate lines are turned on. The select transistors STs connected to the unselected select gate lines are turned off. Thus, the select transistors STs in the selected memory cell are connected to the source line SL electrically. The first row decoder 13 places all of the word lines WL0 to WLm at a low level (0V). The source line driver 15 sets the potential of the source line SL to 0V.

Then, for example, about 1V is applied to each of the bit lines BL0 to BLn. Then, since the memory cell transistor MT of a memory cell MC into which “1” data has been written has a negative threshold voltage, the transistor MT is turned on. Thus, in the memory cell MC connected to the selected select gate line, current flows from the bit line toward the source line SL through the current paths of memory cell transistor MT and select transistor ST. On the other hand, since the memory cell transistor MT of a memory cell MC into which “0” data has been written has a positive threshold voltage, it is in the off state. Thus, no current flows from the bit line toward the source line.

As described above, the potentials on the bit lines BL0 to BLn vary. The variations are amplified by the sense amplifier 12, thereby carrying out the read operation.

<Erase Operation>

The data in all of the memory cells sharing a well region is erased at the same time. Therefore, in the example of FIG. 2, the contents in all the memory cells included in the memory cell array 10 are erased simultaneously.

In FIG. 2, the first row decoder 13 applies the negative potential VBB(−8V) to all of the word lines WL0 to WLm. The potential of the semiconductor substrate (well region) is set at Vpp (12V). As a result, electrons are pulled out of the floating gates of the memory cell transistors of the memory cells MCs into the semiconductor substrate by FN tunneling. As a result, the threshold voltages of all of the memory cells MCs become negative, thereby erasing the data.

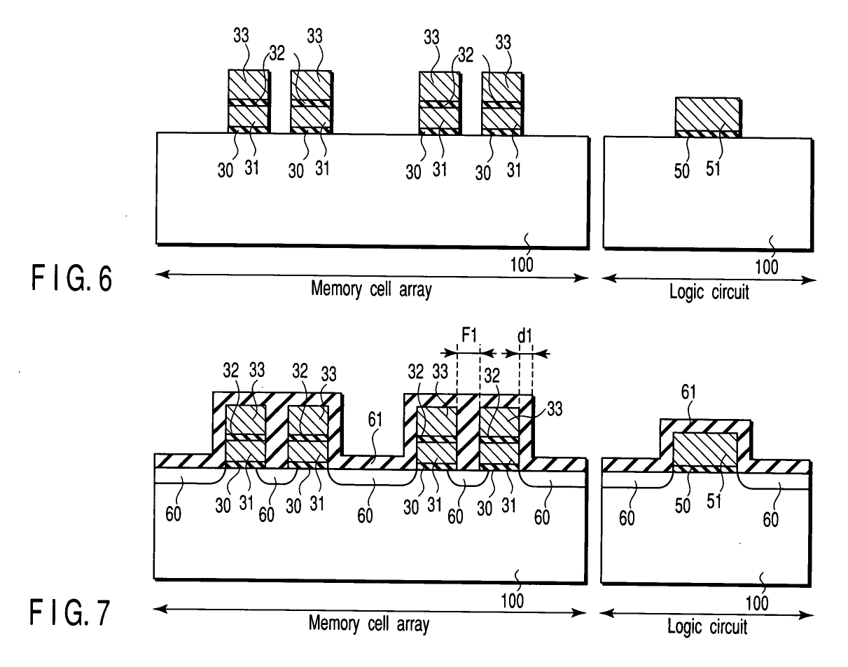

Next, a method of manufacturing the system LSI configured as described above will be explained by reference to FIGS. 6 to 10. FIGS. 6 to 10 are sectional views showing sequentially the processes of manufacturing the system LSI according to the first embodiment. As for the memory cell array area, the sectional views are taken along line 4-4′ of FIG. 3.

In the semiconductor substrate 100, element isolating regions STI are formed by STI (Shallow Trench Isolation) techniques. As a result, stripe-shaped element regions AAs are formed in the memory cell array 11. Then, by thermal oxidation techniques or the like, a gate insulating film 30 is formed to a film thickness of, for example, 8 nm on the semiconductor substrate 100. Then, a polysilicon layer 31 is formed on the gate insulating film 30, to a film thickness of 60 nm. The polysilicon layer 31 functions as the floating gate of a memory cell transistor MT. Next, the polysilicon layer 31 is patterned by photolithographic techniques and anisotropic etching, such as RIE (Reactive Ion Etching) techniques. As a result, in the memory cell array region, the polysilicon layers 31 are separated so as to correspond to the individual memory cell transistors MT. Then, an inter-gate insulating film 32 with a film thickness of 15.5 nm is formed on the polysilicon layer 31 by, for example, CVD techniques or the like. Next, the gate insulating film 30, polysilicon layer 31, and inter-gate insulating film 32 in the logic circuit region are removed by etching. Next, by thermal oxidation techniques or the like, a gate insulating film 50 is formed on the semiconductor substrate 100 in the logic circuit region. Then, a polysilicon layer 33 with a film thickness of, for example, 40 nm is formed on the inter-gate insulating film 32 and on the gate insulating film 50 by CVD techniques or the like. Next, using photolithographic techniques and RIE techniques, the polysilicon layer 33 and inter-gate insulating film 32 in the shunt region SA2 are etched, thereby making a contact hole CH1 reaching the polysilicon layer 31. Thereafter, by CVD techniques or the like, a polysilicon layer is formed, thereby filling the contact hole CH1. As a result, in the select transistor ST, the polysilicon layers 31, 33 are connected.

Next, in the memory cell array region, using photolithographic techniques and RIE techniques, the polysilicon layers 33, 31 and inter-gate insulating film 32 are patterned, thereby forming stripe-shaped stacked gates. Then, in the logic circuit region, the polysilicon layers 33 are patterned into gate electrode patterns, resulting in the configuration shown in FIG. 6. In the logic circuit region, the patterned polysilicon layer 33 becomes a gate electrode 51.

Next, impurities are introduced into the semiconductor substrate 100 in the memory cell array region and peripheral circuit region by ion implantation techniques using the stacked gate and gate electrode as a mask. As a result, an impurity diffused layer 60 is formed in the semiconductor substrate 100 as shown in FIG. 7. The impurity diffused layer 60 formed between the stacked gate of the memory cell transistor MT and the stacked gate of the select transistor ST becomes the source region of the memory cell transistor MT and the drain region of select transistor ST. Then, an insulating film 61 is formed on the top and the sides of each of the stacked gates of the memory cell transistor MT and select transistor ST and on the top and the sides of the MOS transistor in the logic circuit region. The insulating film 61 is made of, for example, a silicon nitride film. As explained in FIG. 5, if the distance between stacked gates is F1 and the thickness of the sidewall insulating film (insulating film 61) is d1, they have the following relationship: F1<2·d1. In other words, they satisfy the expression d1>F1/2. Therefore, the region between the stacked gate of the memory cell transistor MT and the stacked gate of the select transistor ST is filled completely with the insulating film 61.

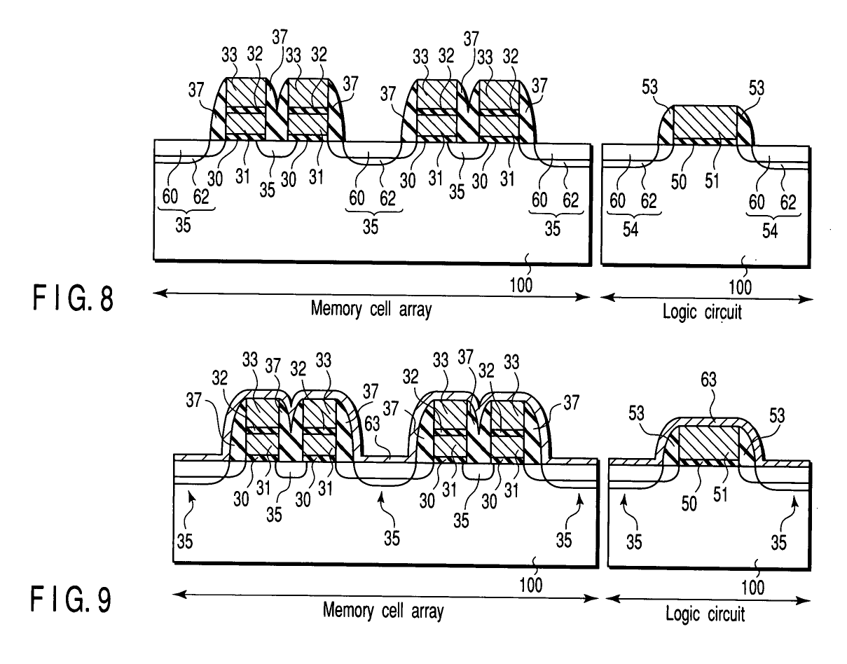

Next, the insulating film 61 is etched by RIE techniques or the like. As a result, the insulating film 61 is left only on the sidewalls of the stacked gates of the memory cell transistor MT and select transistor ST and on the sidewall of the gate electrode 51 of the MOS transistor in the logic circuit region. With the insulating film 61, a sidewall insulating film 37 as shown in FIG. 8 is completed. Then, with the stacked gate, gate electrode 51, and sidewall insulating films 37, 53 as a mask, impurities are introduced into the semiconductor substrate 100 in the memory cell array region and peripheral circuit region by ion implantation techniques. As a result, an impurity diffused layer 62 is formed in the semiconductor substrate 100 as shown in FIG. 8. Then, the impurity diffused layers 60, 62 between adjoining memory cell transistors MT function as the drain region of the memory cell transistor MT. In addition, the impurity diffused layers 60, 62 between adjoining select transistors ST function as the source region of the select transistor ST. In the logic circuit region, too, the impurity diffused layers 60, 62 function as a source or drain region.

Next, as shown in FIG. 9, a metal layer 63 including a Co layer and a Ti/TiN layer is formed by sputtering techniques on the stacked gates of the memory cell transistor MT and select transistor ST, on the gate electrode 51 of the MOS transistor, on the sidewall insulating films 37, 53, and on the semiconductor substrate 100.

Next, annealing is done at a temperature of 475° C. in an atmosphere of, for example, nitrogen. As a result, a silicide layer (TiSi₂, CoSi₂) is formed in the silicon layer in contact with the metal layer 63. That is, a silicide layer 36 is formed in the surface of the polysilicon layer 33 of the stacked gate, in the surface of the drain region of the memory cell transistor MT, and in the surface of the source region 35 of the select transistor ST. In addition, a silicide layer 55 is formed in the surface of the gate electrode 51 in the logic circuit region and in the surface of the source and drain regions 54. Thereafter, the extra metal layer 63 is removed by, for example, wet etching techniques.

Thereafter, by well-known techniques, an interlayer insulating film is formed on the semiconductor substrate. Then, contact plugs and metal wiring layers are formed, which completes the system LSI shown in FIG. 4.

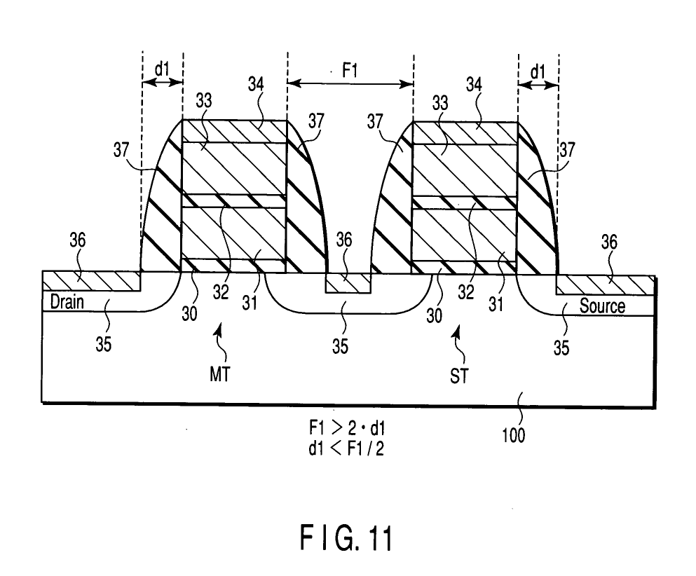

As described above, the flash memory of the first embodiment can improve the reliability of its operation. This will be explained by reference to FIG. 11. FIG. 11 is a sectional view of a memory cell.

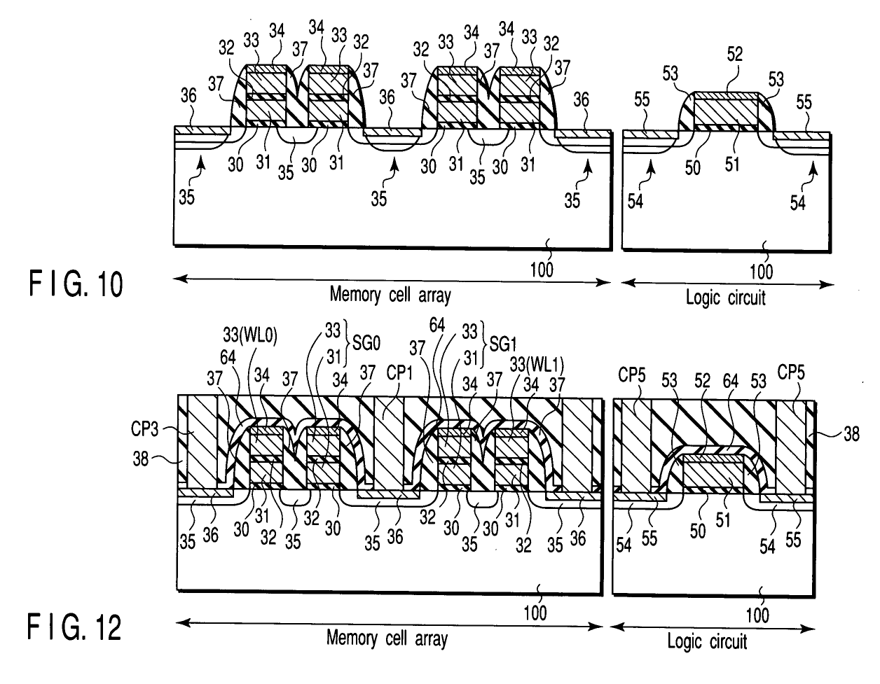

FIG. 11 shows a case where the distance F1 between the stacked gate of the memory cell transistor MT and the stacked gate of the select transistor ST is made larger than twice the film thickness d1 of the sidewall insulating film 37. In this case, the distance between the stacked gates of both of the transistors may not be covered completely with the sidewall insulating film 37. That is, in the process shown in FIG. 8, a part of the impurity diffused layer 35 serving as the source region of the memory cell transistor MT and the drain region of the select transistor ST may be exposed. Then, in the SALICIDE (self-aligned silicidation) process explained in FIGS. 9 and 10, there is a possibility that the silicide layer 36 will be also formed on the impurity diffused layer 35 serving as the source region of the memory cell transistor MT and the drain region of the select transistor ST. Therefore, not only is the reliability of the memory cells impaired, but also the memory cells having a silicide layer 36 and the memory cells having no silicide layer 36 may be mingled between the stacked gates in the memory cell array. As a result, the reliability of the flash memory as a whole is impaired.

With the flash memory of the first embodiment, however, the relationship between the distance F1 between stacked gates and the sidewall insulating film thickness d1 satisfies the expression F1<2·d1. In other words, the relationship satisfies expression d1>F1/2. Specifically, when the distance F1 between stacked gates is determined beforehand, the film thickness d1 of the sidewall insulating film 37 is made greater than F1/2. Conversely, when the film thickness of the sidewall insulating film 37 is determined beforehand, taking the position of the end of the silicide layer 36 into account, the distance F1 between stacked gates is made smaller than 2·d1. As a result, in the process explained in FIG. 7, the region between the stacked gate of the memory cell transistor MT and the stacked gate of the select transistor ST is filled completely with the sidewall insulating film 37. That is, in the process explained in FIG. 8, the impurity diffused layer 35 serving as the source region of the memory cell transistor MT and the drain region of the select transistor ST is not exposed at all. The entire surface of the impurity diffused layer 35 is covered with the sidewall insulating film 37. Accordingly, in the SALICIDE process explained in FIGS. 9 and 10, the silicide layer 36 is prevented from being formed on the impurity diffused layer 35 serving as the source region of the memory cell transistor MT and the drain region of the select transistor ST. Therefore, the reliability of the operation of the memory cells can be improved and therefore the reliability of the flash memory as a whole can be improved.

FIG. 12 is a sectional view of a flash memory according to a first modification of the first embodiment. FIG. 12 is a sectional view taken along line 4-4′ of FIG. 3. As shown in FIG. 12, a barrier insulating film 64 is formed on the stacked gates of the memory cell transistor MT and select transistor ST, on the gate electrode of the MOS transistor in the logic circuit region, on the sidewall insulating films 37, 53, and on the semiconductor substrate 100 in the configuration of FIG. 4 explained in the first embodiment. The barrier insulating film 64 is made of, for example, a silicon nitride film. The barrier insulating film 64 is formed after the formation of the impurity diffused layer 60 in the process shown in FIG. 8. Forming the barrier insulating film 64 prevents the semiconductor substrate from being contaminated in the subsequent processes, which enables the manufacturing yield to be improved. The barrier insulating film 64 can be used as a stopper in the contact hole making process in forming the contact plugs CP1, CP3, CP5.

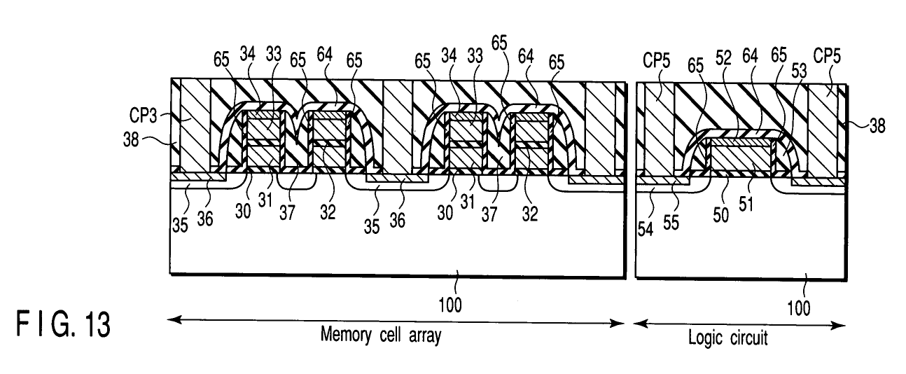

FIG. 13 is a sectional view of a flash memory according to a second modification of the first embodiment. FIG. 13 is a sectional view taken along line 4-4′ of FIG. 3. As shown in FIG. 13, the sidewall insulating films 37, 53 may be formed via a silicon oxide film 65. In other words, each of the sidewall insulating films 37, 53 may be composed of a multilayer film of the silicon nitride film 37 and silicon oxide film 65 and a multilayer film of the silicon nitride film 53 and silicon oxide film 65.

Next, a nonvolatile semiconductor memory device according to a second embodiment of the present invention will be explained. The second embodiment is such that the memory cell array 10 of the flash memory 2 included in the system LSI is replaced with a NAND flash memory in the first embodiment. Therefore, since the configuration excluding the memory cell array 10 is the same as that of the first embodiment, its explanation will be omitted.

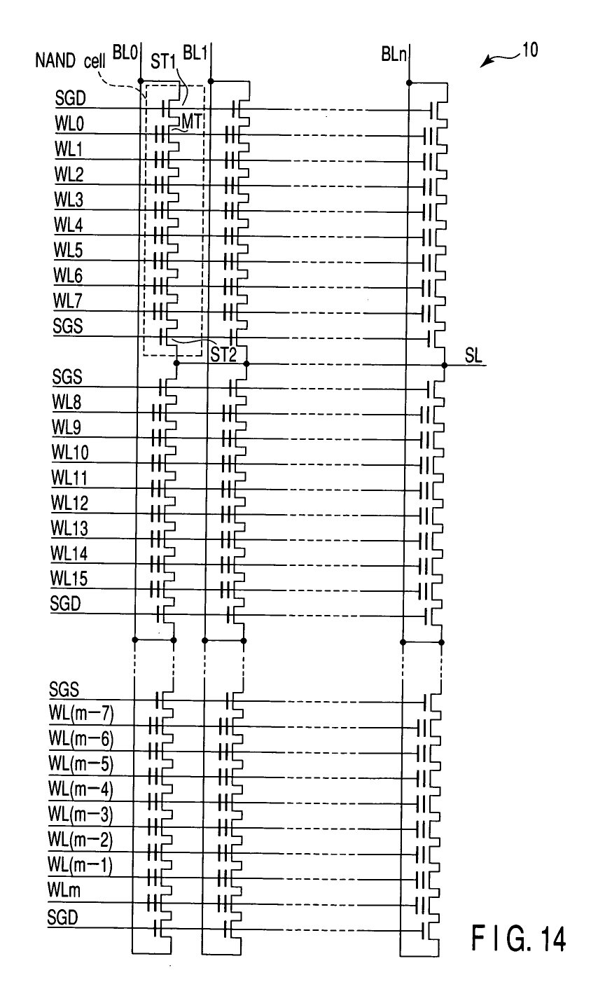

As shown in FIG. 14, the memory cell array 10 has a plurality of NAND cells arranged in a matrix. Each of the NAND cells includes eight memory cell transistors MTs and select transistors ST1, ST2. Each of the memory cell transistors MTs has a stacked gate structure that includes a floating gate formed on a semiconductor substrate with a gate insulating film between the floating gate and the substrate and a control gate formed on the floating gate with an inter-gate insulating film between the control gate and the floating gate. The number of memory cell transistors MTs is not limited to 8 and may be 16 or 32. The number is not restricted to any specific number. Adjacent memory cell transistors share a source and a drain. They are arranged between the select transistors ST1, ST2 in such a manner that their current paths are connected in series. The drain region at one end of the memory cell transistors connected in series is connected to the source region of the select transistor ST1. The source region at the other end of the memory cell transistors connected in series is connected to the drain region of the select transistor ST2.

The control gates of the memory cell transistors MTs in a same row are connected commonly to any one of the word lines WL0 to WLm. The gates of the select transistors ST1, ST2 of the memory cells in a same row are connected commonly to select gate lines SGD, SGS, respectively. The drains of the select transistors ST1 in a same column are connected commonly to any one of the bit lines BL0 to BLn. The sources of the select transistors ST2 are connected commonly to a source line SL and then connected to a source line driver 15. Both of the select transistors ST1, ST2 are not necessarily needed. As long as a NAND cell can be selected, only one of the select transistors ST1 and ST2 may be provided.

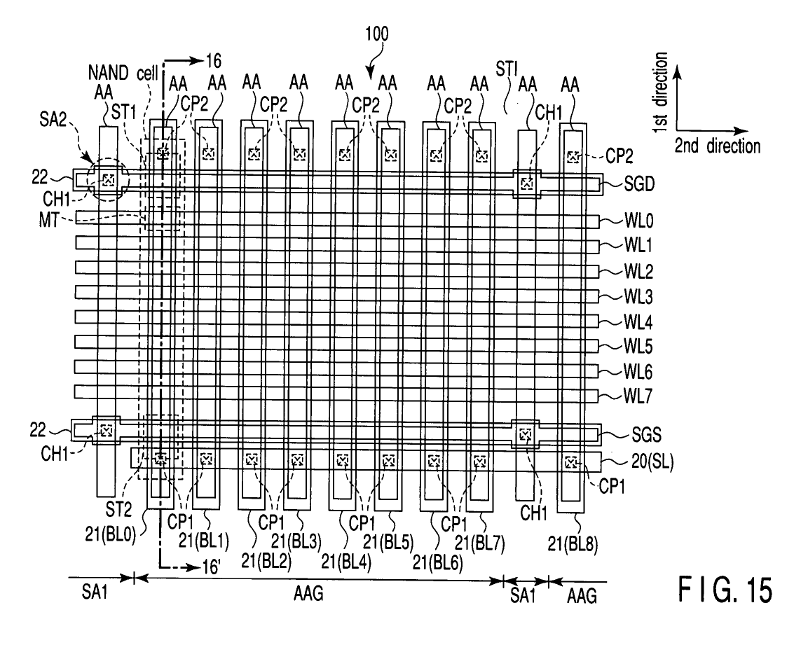

Next, a plane pattern of the memory cell array 10 will be explained by reference to FIG. 15. FIG. 15 is a plan view of a part of the memory cell array 10.

As shown in FIG. 15, in the semiconductor substrate 100, a plurality of stripe-shaped element regions AAs extending in the first direction are formed in the second direction. Stripe-shaped word lines WL0 to WLm, which extend in the second direction, are formed so as to cross the plurality of element regions AAs. Stripe-shaped select gate lines SGD, SGS, which extend in the second direction, are formed so as to sandwich eight word lines between them. Memory cell transistors MTs are formed in the regions where the word lines WL0 to WLm cross the element regions AAs. The select transistors ST1 and ST2 are formed in the regions where the select gate lines SGD and SGS cross the element regions AAs, respectively. Furthermore, floating gates (not shown) isolated on a memory cell transistor MT basis are formed in the regions where the word lines WL0 to WLm cross the element regions AAs.

As in the first embodiment, a stitch region SA1 is provided for each element region group AAG including eight columns of element regions AAs. A shunt region SA2 is provided in the stitch region SA1. In the shunt region SA1, a part of each of the select gate lines SGD, SGS is made wider than the remaining part. The floating gates of the select transistors ST1, ST2 are connected to the control gates through contact holes CH1 made in the inter-gate insulating film in the stitch region SA1.

Then, stripe-shaped metal wiring layers 20 extending in the second direction are formed above the source region of the select transistor ST2. The metal wiring layers 20 become source lines. The metal wiring layer 20 is connected to the source region of the select transistor ST2 by a contact plug CP1. The individual metal wiring layers 20 are connected to one another in a region (not shown) and further connected to the source line driver 15.

In the element region group AAG, stripe-shaped metal wiring layers 21 extending in the first direction are formed in the element region AA. The metal wiring layers 21 function as bit lines BL0 to BLn. They are connected to the drain regions of the select transistor ST1 by contact plugs CP2.

Furthermore, metal wiring layers 22 are formed into stripe-like shapes extending in the second direction. The metal wiring layers 22 are provided for select gate lines SGD, SGS in a one-to-one correspondence. They are connected electrically to the corresponding select gate lines by contact plugs (not shown). Specifically, the individual metal wiring layers 22 function as the shunt lines for select gate lines SGD and SGS.

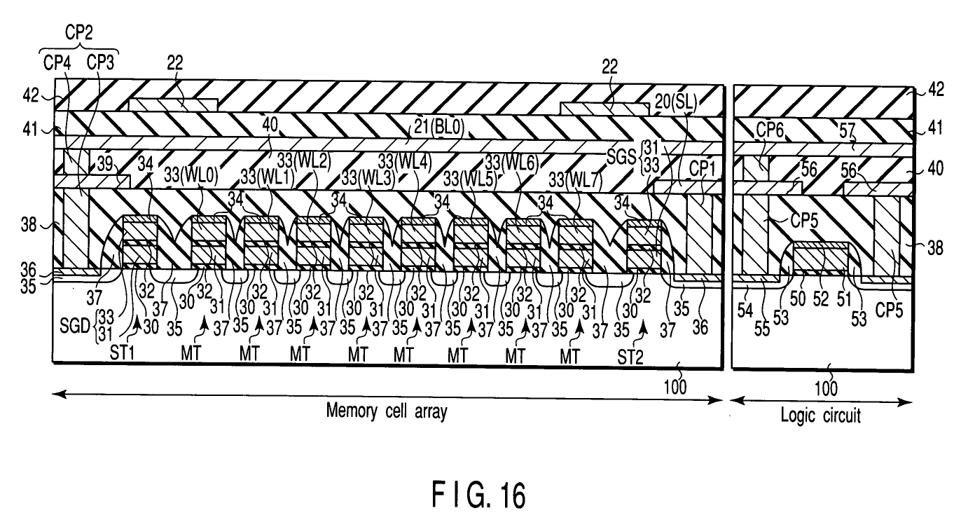

Next, a sectional structure of the NAND flash memory configured as described above will be explained. FIG. 16 is a sectional view taken along line 16-16′ of FIG. 15.

As shown in FIG. 16, gate insulating films 30 are formed on the element region AA of the semiconductor substrate 100. The gate electrodes of memory cell transistors MTs and select transistors ST1, ST2 are formed on the gate insulating films 30. Each of the gate electrodes of the memory cell transistors MT and select transistors ST1, ST2 includes a polysilicon layer 31 formed on the gate insulating film 30, an inter-gate insulating film 32 formed on the polysilicon layer 31, a polysilicon layer 33 formed on the inter-gate insulating film 32, and a silicide layer 34 formed on the polysilicon layer 33. The inter-gate insulating film 32 is composed of, for example, an ON film, an NO film, or an ONO film as in the first embodiment. In the memory cell transistor MT, the polysilicon layers 31, which are separated from one another between element regions AAs adjoining in the word line direction, function as floating gates. In addition, the polysilicon layers 33 function as control gates (word lines WLs). The polysilicon layers 33 are connected to one another between element regions AAs adjoining in the word line direction. In each of the select transistors ST1, ST2, a part of the inter-gate insulating film 32 is removed in the shunt region and the polysilicon layers 31, 33 are connected electrically. Then, the polysilicon layers 31, 33 function as select gate lines SGD, SGS. In the select transistors ST1, ST2, the polysilicon layer 33 and polysilicon layer 31 are not separated between element regions AAs adjoining in the word line direction and are connected to each other.

An impurity diffused layer 35 functioning as a source and drain regions is formed in the surface of the semiconductor substrate 100 located between adjoining gate electrodes. The impurity diffused layer 35 is shared by adjoining transistors. Specifically, the impurity diffused layer between two adjoining select transistors ST1 functions as a drain region for the two select transistors ST1. The impurity diffused layer 35 between two adjoining select transistors ST2 functions as a source region for the two select transistors ST2. In addition, the impurity diffused layer 35 between two adjoining memory cell transistors MTs function as a source and drain regions for the two memory cell transistors MTs. Moreover, the impurity diffused layer 35 between the memory cell transistor MT and select transistor ST1 adjacent to each other functions as the drain region of the memory cell transistor MT and the source region of the select transistor ST1. On the other hand, the impurity diffused layer 35 between the memory cell transistor MT and select transistor ST2 adjacent to each other functions as the source region of the memory cell transistor MT and the drain region of the select transistor ST2. A silicide layer 36 is formed in the surface of the drain region 35 of the select transistor ST1 and in the surface of the source region 35 of the select transistor ST2. In the source and drain regions 35 of the memory cell transistor MT, in the source region 35 of the select transistor ST1, and in the drain region 35 of the select transistor ST2, no silicide layer is formed. A sidewall insulating film 37 is formed on the side of the gate electrode (stacked gate) of each of the memory cell transistor MT and select transistors ST1, ST2. The sidewall insulating film 37 is formed on the side facing the source region 35 of the stacked gate and on the side facing the drain region 35. The region between the stacked gates of the memory cell transistor MT and each of the select transistors ST1, ST2 is filled with the sidewall insulating film 37. Thus, the top of the source and drain regions of the memory cell transistor MT, the top of the source region of the select transistor ST1, and the top of the drain region of the select transistor ST2 are covered with the sidewall insulating film 37.

An interlayer insulating film 38 is formed on the semiconductor substrate 100 so as to cover the memory cell transistor MT and select transistors ST1, ST2. In the interlayer insulating film 38, a contact plug CP1 is formed which reaches the silicide layer 36 formed in the source region 35 of the select transistor ST2. A metal wiring layer 20 connected to the contact plug CP1 is formed on the interlayer insulating film 38. The metal wiring layer 20 functions as a source line SL. In the interlayer insulating film 38, a contact plug CP3 is formed which reaches the silicide layer 36 formed in the drain region 35 of the select transistor ST1. A metal wiring layer 39 to be connected to the contact plug CP3 is formed on the interlayer insulating film 38.

An interlayer insulating film 40 is formed on the interlayer insulating film 38 so as to cover the metal wiring layers 20, 39. A contact plug CP4 reaching the metal wiring layer 39 is formed in the interlayer insulating film 40. A metal wiring layer 21 connected commonly to a plurality of contact plugs CP4 is formed on the interlayer insulating film 40. The metal wiring layer 21 functions as a bit line BL.

An interlayer insulating film 41 is formed on the interlayer insulating film 40 so as to cover the metal wiring layer 21. A metal wiring layer 22 is formed on the interlayer insulating film 41. The metal wiring layer 22 is connected to the silicide layers 34 of the select transistors ST1, ST2 in the stitch region SA1. An interlayer insulating film 42 is formed on the interlayer insulating film 41, so as to cover the metal wiring layer 22.

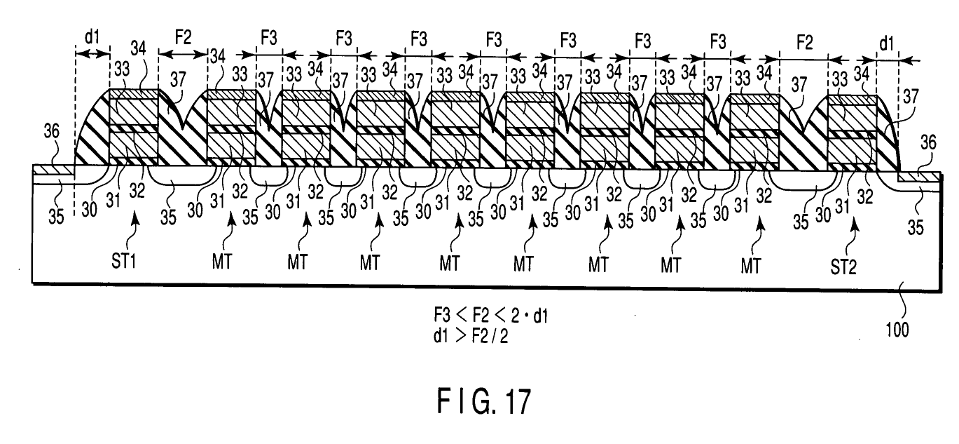

In the NAND memory cell configured as described above, the distance between the stacked gates and the thickness of the sidewall insulating film 37 have the relationship as shown in FIG. 17. FIG. 17, which is an enlarged view of FIG. 16, is a sectional view of a NAND memory cell. As shown in FIG. 16, assuming that the distance between the stacked gate of the select transistor ST1 and its adjoining memory cell transistor MT and the distance between the stacked gate of the select transistor ST2 and its adjoining memory cell transistor MT are each F2, the distance between the stacked gates of adjoining memory cell transistors MTs is F3, and the sidewall insulating film thickness is d1, they have the following relationship: F3<F2<2·d1. In other words, they satisfy the expression d1>F2/2. A silicide layer 36 is formed in the surface of the drain region 35 of the select transistor ST1 and in the surface of the source region 35 of the select transistor ST2. Therefore, the surface of a part of each of the drain region 35 of the select transistor ST1 and the source region 35 of the select transistor ST2 is lower than the surface of the channel region of each of the select transistors ST1, ST2 by the film thickness of the silicide layer 36. On the other hand, No silicide layer is formed in the surface of the source and drain regions 35 of the memory cell transistor MT, in the surface of the source region 35 of the select transistor ST1, and in the surface of the drain region 35 of the select transistor ST2. As a result, the surface of the source and drain regions 35 of the memory cell transistor MT, the source region 35 of the select transistor ST1, and the surface of the drain region 35 of the select transistor ST2 are in the same plane as that of the surface of the channel region of each of the memory cell transistor MT and the select transistors ST1, ST2.

Since the configuration of the logic circuit is the same as that of FIG. 4 in the first embodiment, its explanation will be omitted.

In addition, since the operation of the NAND flash memory configured as described above is the same as in the prior art, its explanation will be omitted.

A conventional NAND flash memory manufacturing method can be applied to the method of manufacturing the system LSI with the above configuration. As explained in the first embodiment, after stripe-shaped stacked gates are formed (see FIG. 6), an insulating film 61 is formed on the stacked gates and on the semiconductor substrate 100 (see FIG. 7). In this case, as explained in FIG. 17, the distance between stacked gates and the sidewall insulating film thickness are caused to meet the expression F3<F2<2·d1. As a result, the region between the stacked gates of memory cell transistors MTs and the region between the stacked gate of the memory cell transistor MT and the stacked gate of each of the select transistors ST1, St2 are filled completely with the insulating film 61. Thereafter, the processes explained in the first embodiment are carried out, which completes the NAND flash memory shown in FIG. 16.

As described above, a flash memory according to the second embodiment is capable of improving the reliability of operation as in the first embodiment.

Specifically, with the flash memory of the second embodiment, the distance F3 between the stacked gate of the memory cell transistor MT and each of the stacked gates of the select transistors ST1, ST2, the distance F2 between the stacked gates of the memory cell transistors MTs, and the sidewall insulating film thickness d1 are caused to satisfy the expression F3<F2<2·d1. In other words, they satisfy the expression d1>F2/2. Specifically, when the distance F2 between stacked gates is determined beforehand, the film thickness d1 of the sidewall insulating film 37 is made greater than F2/2. Conversely, when the film thickness of the sidewall insulating film 37 is determined beforehand, the distance F2 between stacked gates is made smaller than 2·d1. As a result, the region between the stacked gate of the memory cell transistor MT and the stacked gate of each of the select transistors ST1, ST2 and the region between the stacked gates of memory cell transistors MTs are filled completely with the sidewall insulating film 37. That is, at the stage of carrying out the SALICIDE process, the impurity diffused layer 35 serving as the source-drain region of the memory cell transistor, the source region of the select transistor ST1, and the drain region of the select transistor ST2 are not exposed at all. The entire surface of the impurity diffused layer 35 is covered with the sidewall insulating film 37. Accordingly, in the SALICIDE process, the silicide layer 36 is prevented from being formed on the impurity diffused layer 35 serving as the source and drain regions of the memory cell transistor, the source region of the select transistor ST1, and the drain region of the select transistor ST2. Therefore, the reliability of the operation of the memory cells can be improved and therefore the reliability of the flash memory as a whole can be improved.

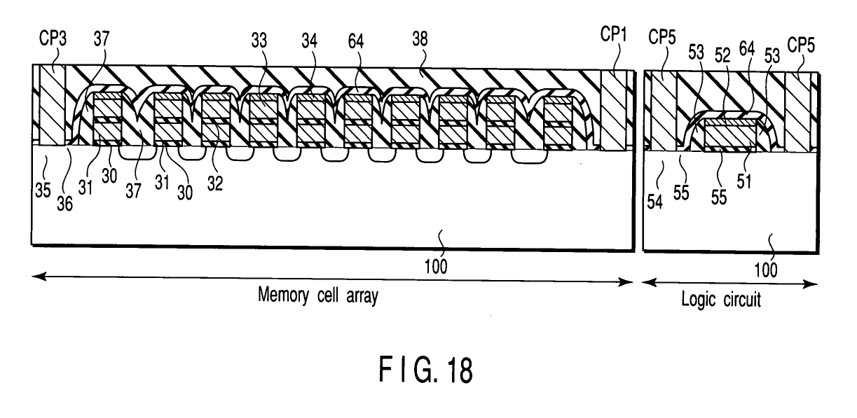

FIG. 18 is a sectional view of a flash memory according to a first modification of the second embodiment. FIG. 18 is a sectional view taken along line 16-16′ of FIG. 15. As shown in FIG. 18, the barrier insulating film 64 may be formed on the stacked gates of the memory cell transistor MT and select transistors ST1, ST2, on the gate electrode of the MOS transistor in the logic circuit region, on the sidewall insulating films 37, 53, and on the semiconductor substrate 100 in the configuration of FIG. 16 explained in the second embodiment. The barrier insulating film 64 is as explained in the first modification of the first embodiment.

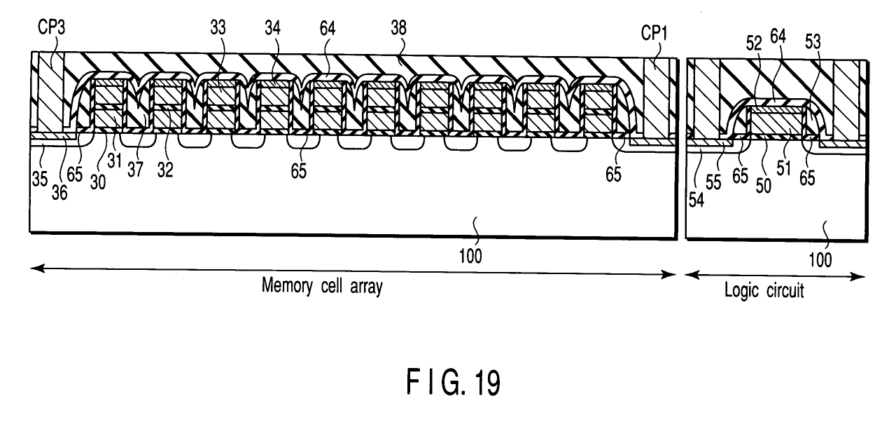

FIG. 19 is a sectional view of a flash memory according to a second modification of the second embodiment. FIG. 19 is a sectional view taken along line 16-16′ of FIG. 15. As shown in FIG. 19, the sidewall insulating films 37, 53 may be formed on a silicon oxide film 65 in the configuration of FIG. 16 explained in the second embodiment. In other words, each of the sidewall insulating films may be formed of a multilayer film of the silicon nitride film 37 and silicon oxide film 65 or a multilayer film of the silicon nitride film 53 and silicon oxide film 65.

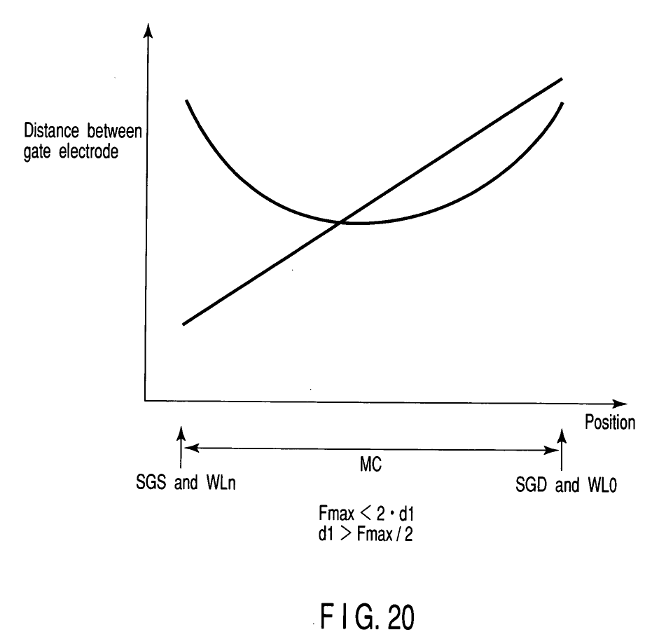

In the second embodiment, the distance F3 between the stacked gates of memory cell transistors MTs is constant, the distance F2 between the stacked gate of the memory cell transistors MT and each of the stacked gates of the select transistors ST1, ST2 is constant, and the expression F2>F3 is satisfied. However, the second embodiment is not restricted to this. FIG. 20 is a graph showing the relationship between the position in an NAND cell and the distance between gate electrodes. On the abscissa, the position of the select transistor ST2 is at left on the sheet of paper and the position of the select transistor ST1 is at right on the sheet. The ordinate indicates the distance between gate electrodes. As shown in FIG. 20, the distance between gate electrodes may change in such a manner that it becomes smaller as the position moves from the select transistor ST1 toward the select transistor ST2. In addition, the distance between gate electrodes may change in such a manner that it takes the smallest value in the central part of the NAND cell. Of course, it may take the greatest value in the central part of the NAND cell. As described above, even when the distance between gate electrodes changes, the greatest distance Fmax between gate electrodes and the sidewall insulating film thickness d1 have only to satisfy the expression Fmax<2·d1 or d1>Fmax/2.

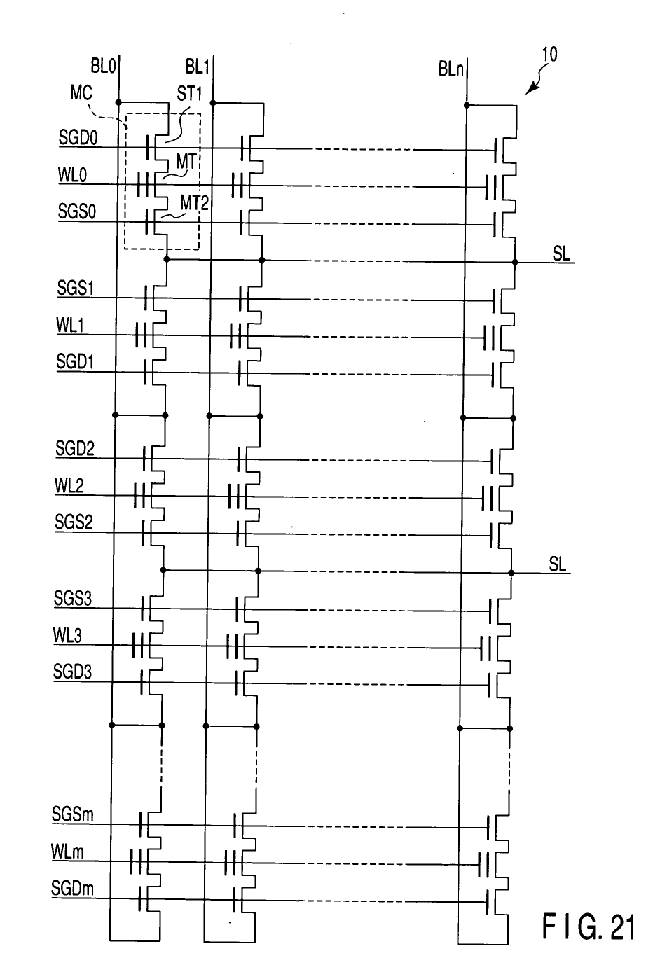

Hereinafter, a nonvolatile semiconductor memory device according to a third embodiment of the present invention will be explained. The third embodiment is such that the memory cell array 10 of the flash memory 2 included in the system LSI is replaced with the one with the configuration shown in FIG. 21 in the first embodiment. Since the configuration excluding the memory cell array 10 is the same as that of the first embodiment, its explanation will be omitted.

The memory cell array 10 has a plurality of ((m+1)×(n+1)) memory cells MCs (m and n are natural numbers) arranged in a matrix. Each of the memory cells MCs includes a memory cell transistor MT and select transistors ST1, ST2, which have their current paths connected in series with one another. The current path of the memory cell transistor MT is connected between the current paths of the select transistors ST1, ST2. That is, this is equivalent to use of one memory cell transistor MT in a NAND cell explained in the second embodiment. The memory cell transistor MT has a stacked gate structure that includes a floating gate formed on a semiconductor substrate with a gate insulating film interposed between the gate and the substrate and a control gate formed on the floating gate with an inter-gate insulating film interposed between the control gate and the floating gate. The source region of the select transistor ST1 is connected to the drain region of the memory cell transistor MT. The source region of the memory cell transistor MT is connected to the drain region of the select transistor ST2. Memory cells MCs adjoining each other in the column direction share the drain region of the select transistor ST1 or the source region of the select transistor ST2.

The control gates of the memory cell transistors MTs of the memory cells MCs in a same row are connected commonly to any one of word lines WL0 to WLm. The gates of the select transistors ST1 of the memory cells in a same row are connected commonly to any one of select gate lines SGD0 to SGDm. The gates of the select transistors ST2 of the memory cells in a same row are connected commonly to any one of select gate lines SGS0 to SGSm. The drains of the select transistors ST1 of the memory cells MCs in a same column are connected commonly to any one of bit lines BL0 to BLm. The sources of the select transistors ST2 of the memory cells MCs are connected commonly to a source line SL and then connected to a source line driver 15.

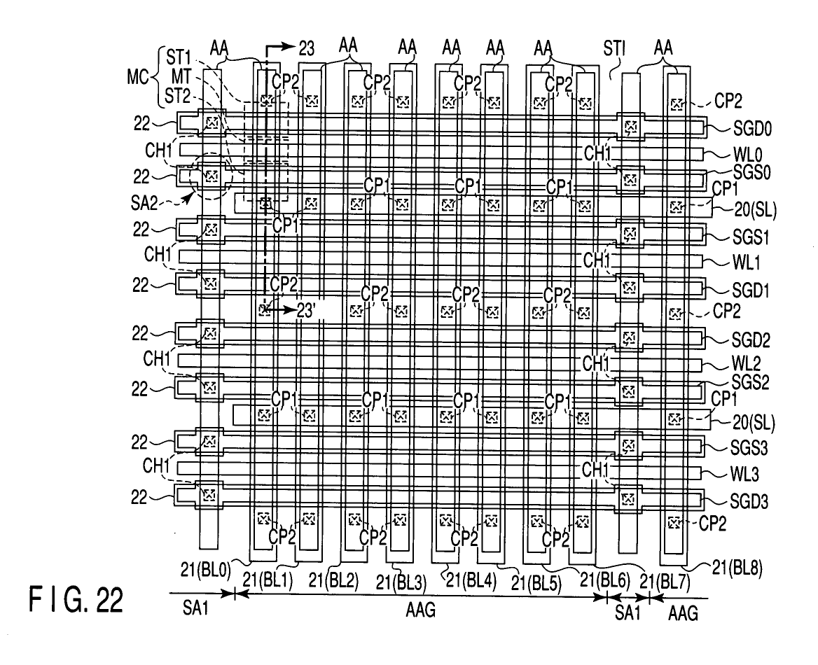

A plane pattern of the memory cell 10 will be explained by reference to FIG. 22. FIG. 22 is a plan view of a part of the memory cell array 10.

As shown in FIG. 22, in the semiconductor substrate 100, a plurality of stripe-shaped element regions AAs extending in the first direction are formed in the second direction. Stripe-shaped word lines WL0 to WLm and select gate lines SGD0 to SGDm, SGS0 to SGSm, which extend in the second direction, are formed so as to cross the plurality of element regions AAs. The memory cell transistors MTs are formed in the regions where the word lines WL0 to WLm cross the element regions AAs. The select transistors ST1 are formed in the regions where the select gate lines SGD0 to SGDm cross the element regions AAs. The select transistors ST2 are formed in the regions where the select gate lines SGS0 to SGSm cross the element regions AAs. Furthermore, the floating gates (not shown), which are isolated on a memory cell transistor MT basis, are formed in the regions where the word lines WL0 to WLm cross the element regions AAs. As in the first and second embodiments, the floating gates and control gates of the select transistors are connected in the stitch regions SA1.

A stripe-shaped metal wiring layer 20 extending in the second direction is formed on the source region of the select transistor ST2. The metal wiring layer 20 is to act as a source line. The metal wiring layer 20 is connected to the source region of the select transistor ST2 by a contact plug CP1. The individual metal wiring layers 20 are connected to one another in a region (not shown) and then connected to the source line driver 15.

In the element region group AAG, stripe-shaped metal wiring layers 21 extending in the first direction are formed in the element region AA. The metal wiring layers 21 function as bit lines BL0 to BLn. They are connected to the drain regions of the select transistors ST1 by contact plugs CP2.

Furthermore, metal wiring layers 22 are formed into strip-like shapes extending in the second direction. The metal wiring layers 22 are provided for the select gate lines in a one-to-one correspondence. They are connected electrically to the corresponding select gate lines by contact plugs (not shown). Specifically, the individual metal wiring layers 22 function as the shunt lines for the select gate lines SGD0 to SGDm, SGS0 to SGSm.

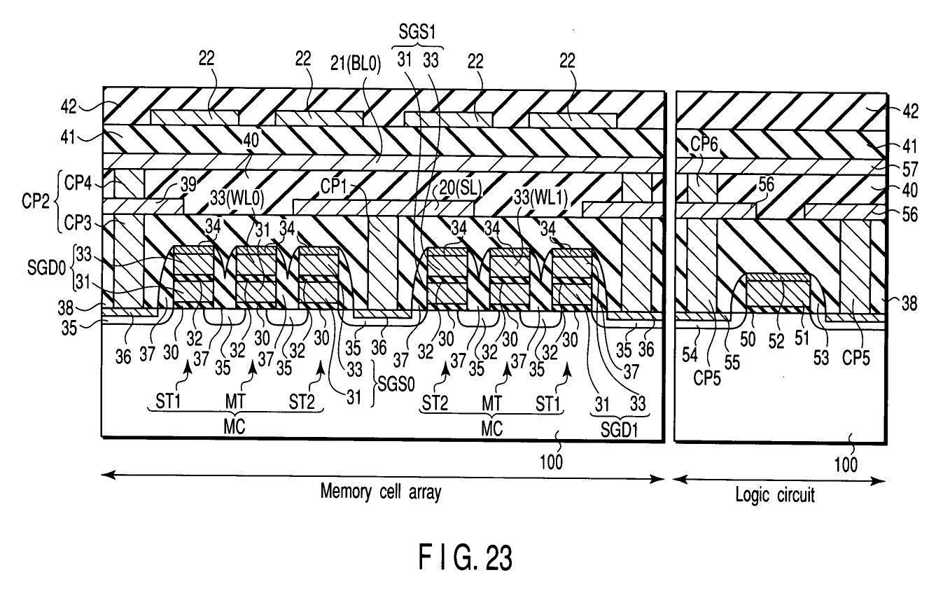

Next, a sectional structure of the flash memory configured as described above will be explained. FIG. 23 is a sectional view taken along line 23-23′ of FIG. 22.

As shown in FIG. 23, gate insulating films 30 are formed in the element region AA of the semiconductor substrate 100. The gate electrodes of the memory cell transistors MTs and select transistors ST1, ST2 are formed on the gate insulating films 30. Each of the gate electrodes of the memory cell transistor MT and select transistors ST1, ST2 includes a polysilicon layer 31 formed on the gate insulating film 30, an inter-gate insulating film 32 formed on the polysilicon layer 31, a polysilicon layer 33 formed on the inter-gate insulating film 32, and a silicide layer 34 formed on the polysilicon layer 33. The inter-gate insulating film 32 is formed of, for example, an ON film, an NO film, or an ONO film. In the memory cell transistor MT, the polysilicon layers 31, which are separated from one another between element regions AAs adjoining in the word line direction, function as the floating gates. In addition, the polysilicon layers 33 function as control gates (word lines WLs). The polysilicon layers 33 are connected to each other between element regions AAs adjoining in the word line direction. In each of the select transistors ST1, ST2, a part of the inter-gate insulating film 32 is removed in the shunt region and the polysilicon layers 31, 33 are connected electrically. Then, the polysilicon layers 31, 33 function as select gate lines SGS, SGD. In the select transistors ST1, ST2, the polysilicon layer 33 and polysilicon layer 31 are not separated between element regions AAs adjoining in the word line direction and are connected to each other. That is, as in the memory cell transistor MT, the floating gates are not separated cell by cell and are all connected to one another.

An impurity diffused layer 35 functioning as a source and drain regions is formed in the surface of the semiconductor substrate 100 located between adjoining gate electrodes. The impurity diffused layer 35 is shared by adjoining transistors. Specifically, the impurity diffused layer 35 between two adjoining select transistors ST1 functions as a drain region for the two select transistors ST1. The impurity diffused layer 35 between two adjoining select transistors ST2 function as a source region for two select transistors. ST2. Moreover, the impurity diffused layer 35 between the memory cell transistor MT and select transistor ST1 adjacent to each other functions as the drain region of the memory cell transistor MT and the source region of the select transistor ST1. In addition, the impurity diffused layer 35 between the memory cell transistor MT and select transistor ST2 adjacent to each other functions as the source region of the memory cell transistor MT and the drain region of the select transistor ST2. A silicide layer 36 is formed in the surface of the drain region 35 of the select transistor ST1 and in the surface of the source region 35 of the select transistor ST2. No silicide layer is formed in the source and drain regions 35 of the memory cell transistor, in the source region 35 of the select transistor ST1, and in the drain region 35 of the select transistor ST2. A sidewall insulating film 37 is formed on the sides of the gate electrode (stacked gate) of each of the memory cell transistor MT and select transistors ST. The sidewall insulating film 37 is formed on the side facing the source region 35 of the stacked gate and on the side facing the drain region 35. The region between the stacked gates of the memory cell transistor MT and select transistor ST is filled with the sidewall insulating film 37. Thus, the top of the source and drain regions of the memory cell transistor MT, the top of the source region of the select transistor St1, and the top of the drain region of the select transistor ST2 are covered with the sidewall insulating film 37.

Since the remaining configuration is the same as that of the second embodiment, its explanation will be omitted.

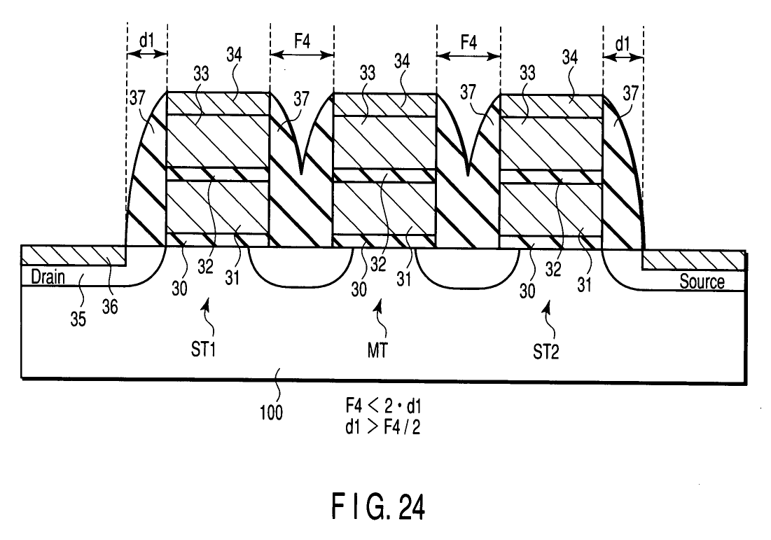

In the memory cell configured as described above, the distance between the gates of the memory cell transistor MT and select transistor ST adjacent to each other and the thickness of the sidewall insulating film 37 have the relationship as shown in FIG. 24. FIG. 24, which is an enlarged view of FIG. 23, is a sectional view of a memory cell. As shown in FIG. 24, if the distance between stacked gates is F4 and the sidewall insulating film thickness is d1, they have the following relationship: F4<2·d1. In other words, they satisfy the expression d1>F4/2. A silicide layer 36 is formed in the surface of the drain region 35 of the select transistor ST1 and in the surface of the source region 35 of the select transistor ST2. Therefore, the surface of a part of each of the drain region 35 of the select transistor ST1 and the source region 35 of the select transistor ST2 is lower than the surface of the channel region of each of the memory cell transistor MT, the select transistor ST1, and the select transistor ST2 by the film thickness of the silicide layer 36. On the other hand, no silicide layer is formed in the surface of the source and drain regions 35 of the memory cell transistor MT, in the surface of the source region 35 of the select transistor ST1, and in the surface of the drain region 35 of the select transistor ST2. As a result, the surface of the source and drain regions 35 of the memory cell transistor MT, the surface of the source region of the select transistor ST1, and the surface of the drain region 35 of the select transistor ST2 are in the same plane as that of the surface of the channel region of each of the memory cell transistor MT and the select transistors ST1, ST2.

Since the configuration of the logic circuit region is the same as that of the first embodiment, its explanation will be omitted.

The operation of the flash memory 2 with the above configuration will be explained.

<Write Operation>

Data is written simultaneously into all of the memory cells connected to any one of the word lines. As in the first embodiment, either “0” data or “1” data is written, depending on whether electrons are injected into the floating gate of the memory cell transistor MT. Electrons are injected into the floating gate by Fowler-Nordheim (FN) tunneling.

Hereinafter, the details of a write operation will be explained by reference to FIG. 2 and FIG. 21.

First, in FIG. 2, write data (“1” or “0”) is input from an I/O terminal (not shown). Then, the first row decoder 13 selects one of the word lines WL0 to WLm. Then, the first row decoder 13 supplies Vpp (e.g., 12V) to the selected word line. The second row decoder 14 selects any one of the select gate lines SGD0 to SGDm. Then, the second row decoder 14 supplies a high level (e.g., Vcc=1.5V) to the selected select gate line SGD. Thus, the select transistor ST1 connected to the selected select gate line SGD is turned on. Furthermore, the second row decoder 13 makes all of the select gate lines SGS0 to SGSm unselected. That is, the second row decoder 13 supplies a low level (e.g., VBB=−8V) to the select gate lines SGS0 to SGSm. Thus, all of the select transistors ST2 are turned off. The potential of the semiconductor substrate in which the memory cells have been formed is also placed at VBB (−8V).

As a result, the potential corresponding to “1” data or “0” data is applied to the drain region of the memory cell transistor MT via the corresponding one of the bit lines BL0 to BLn. Then, Vpp (12V) is applied to the selected word line WL, 0V is applied to the drain region of the memory cell transistor MT into which “1” data is to be written, and VBB (−8V) is applied to the drain region of the memory cell transistor MT into which “0” data is to be written. Thus, in the memory cell transistor MT into which “1” data is to be written, no electron is injected into the floating gate. On the other hand, in the memory cell transistor MT into which “0” data is to be written, electrons are injected into the floating gate by FN tunneling.

As described above, the write operation is carried out.

<Read Operation>

In a read operation, data can be read simultaneously from a plurality of memory cells connected to any one of the word lines.

Hereinafter, the details of a read operation will be explained by reference to FIG. 2 and FIG. 21.

First, in FIG. 2, the second row decoder 14 selects any one of the select gate lines SGD0 to SGDm and any one of the select gates lines SGS0 to SGSm. A high level (e.g., Vcc) is supplied to the selected select gate line. All of the unselected gate lines are at a low level (e.g., 0V). As a result, the select transistors ST1, ST2 connected to the selected gate line are in the on state and the select transistors ST1, ST2 connected to the unselected gate lines are in the off state. Consequently, the select transistor ST2 in the selected memory cell is connected electrically to the source line SL. Furthermore, the first row decoder 13 places all of the word lines WL0 to WLm at the low level (0V). The source line driver 15 places the potential of the source line SL at 0V.

Then, for example, a voltage of about 1V is applied to each of the bit lines BL0 to BLn. This turns on the memory cell transistor MT of the memory cell MC into which “1” data has been written, since its threshold voltage is negative. As a result, in the memory cell MC connected to the selected select gate line, current flows from the bit line through the current paths of the select transistor ST1, memory cell transistor MT, and select transistor ST2 toward the source line SL. On the other hand, the memory cell transistor MT of the memory cell MC into which “0” data has been written is in the off state, since its threshold voltage is positive. Thus, no current flows from the bit line toward the source line SL.

As a result, the potentials on the bit lines BL0 to BLn vary. The variations are sensed by the sense amplifier 12, thereby carrying out a read operation.

<Erase Operation>

Since data is erased in the same manner as in the first embodiment, its explanation will be omitted.

A method of manufacturing a system LSI with the above configuration is almost the same as in the first embodiment. In FIGS. 6 to 10, the select transistor ST1 is also formed on the drain region of the memory cell transistor MT. Then, after a stripe-like stacked gate is formed (see FIG. 6), the insulating film 61 is formed on the stacked gate and on the semiconductor substrate 100 (see FIG. 7). At this time, as explained in FIG. 24, the distance between stacked gates and the sidewall insulating film thickness are caused to satisfy the expression F4<2·d1. As a result, the region between the stacked gate of the memory cell transistor MT and the stacked gate of the select transistor ST1 and the region between the stacked gate of the memory cell transistor MT and the stacked gate of the select transistor ST2 are filled completely with the insulating film 61.

As described above, a flash memory according to the third embodiment is capable of improving the reliability of operation as in the first embodiment.

Specifically, with the flash memory of the third embodiment, the distance F4 between the stacked gate of the memory cell transistor MT and the stacked gate of each of the select transistors ST1, ST2 and the sidewall insulating film thickness d1 are caused to satisfy the expression F4<2·d1. In other words, they satisfy the expression d1>F4/2. Specifically, when the distance F4 between stacked gates is determined beforehand, the film thickness d1 of the sidewall insulating film 37 is made greater than F4/2. Conversely, when the film thickness of the sidewall insulating film 37 is determined beforehand, the distance F4 between stacked gates is made smaller than 2·d1. As a result, the region between the stacked gate of the memory cell transistor MT and the stacked gate of each of the select transistors ST1, ST2 is filled completely with the sidewall insulating film 37. That is, at the stage of carrying out the SALICIDE process, the impurity diffused layer 35 serving as the source and drain regions of the memory cell transistor MT, the source region of the select transistor ST1, and the drain region of the select transistor ST2 are not exposed at all. The entire surface of the impurity diffused layer 35 is covered with the sidewall insulating film 37. Accordingly, in the SALICIDE process, the silicide layer 36 is prevented from being formed on the impurity diffused layer 35 serving as the source and drain regions of the memory cell transistor, the source region of the select transistor ST1, and the drain region of the select transistor ST2. Therefore, the reliability of the operation of the memory cells can be improved and therefore the reliability of the flash memory as a whole can be improved.

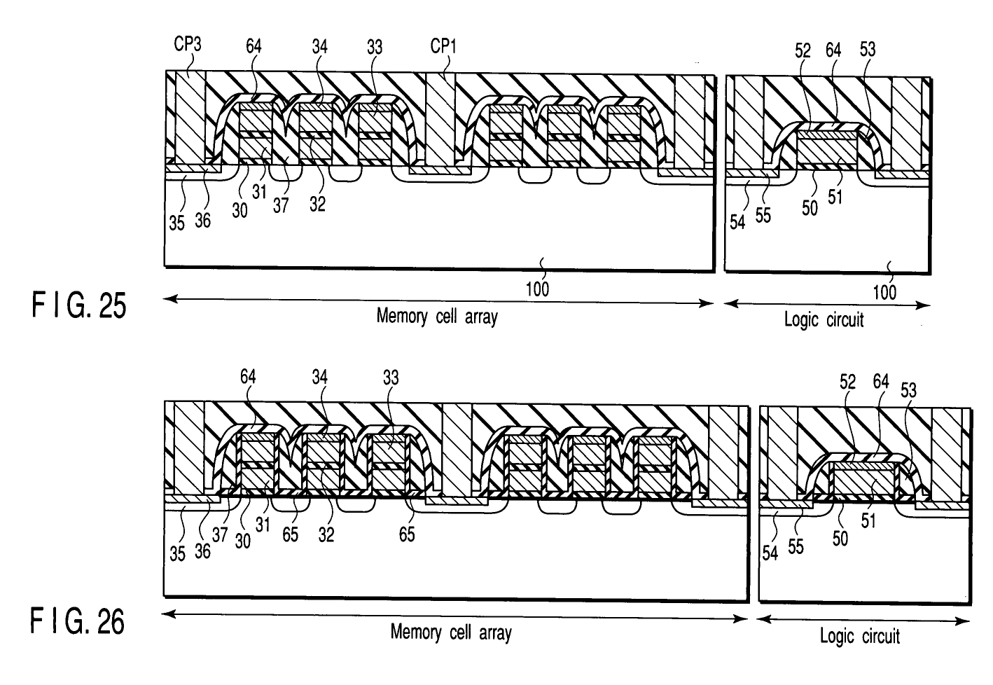

FIG. 25 is a sectional view of a flash memory according to a first modification of the third embodiment. FIG. 25 is a sectional view taken along line 23-23′ of FIG. 22. As shown in FIG. 25, the barrier insulating film 64 may be formed on the stacked gates of the memory cell transistor MT and select transistors ST1, ST2, on the gate electrode of the MOS transistor in the logic circuit region, on the sidewall insulating films 37, 53, and on the semiconductor substrate 100 in the configuration of FIG. 23 explained in the third embodiment. The barrier insulating film 64 is as explained in the first modification of the first embodiment.

FIG. 26 is a sectional view of a flash memory according to a second modification of the third embodiment. FIG. 26 is a sectional view taken along line 23-23′ of FIG. 22. As shown in FIG. 26, the sidewall insulating films 37, 53 may be formed on a silicon oxide film 65 as in the second modification of the first embodiment in the configuration of FIG. 23 explained in the third embodiment.

In the third embodiment, the distance F4 between the stacked gate of the memory cell transistors MT and the stacked gate of each of the select transistors ST1, ST2 has been constant. However, the distance between the stacked gate of the memory cell transistors MT and the stacked gate of the select transistor ST1 may differ from the distance between the stacked gate of the memory cell transistors MT and the stacked gate of the select transistor ST2. In this case, the greater one of the distances F4 has only to satisfy the expression F4<2·d1.

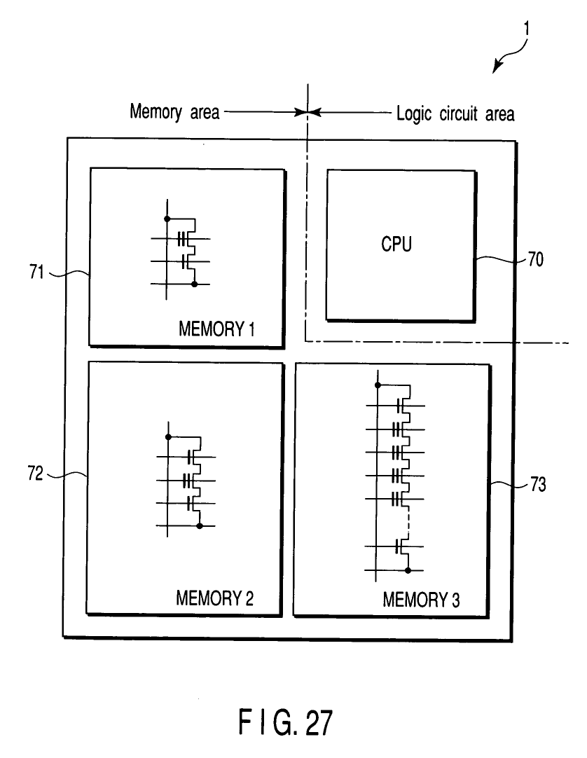

Next, a nonvolatile semiconductor memory device according to a fourth embodiment of the present invention will be explained. The fourth embodiment is such that the flash memory 2 explained in each of the first to third embodiments is embedded into a single system LSI. FIG. 27 is a block diagram of a system LSI according to the fourth embodiment.

As shown in FIG. 27, a system LSI 1 has a logic circuit area and a memory area. A CPU 70 is provided in the logic circuit area, for example. In the memory area, there are provided a flash memory 71 explained in the first embodiment, a flash memory 72 explained in the third embodiment, and a NAND flash memory 73 explained in the second embodiment. Each of the memory cells in the flash memory 71 has two transistors connected in series, which provides a higher current driving capability than that of the other memory cells. Therefore, the flash memory 71 is suitable for high-speed reading. As shown in FIG. 27, when the flash memory 71 is embedded in the same chip as the CPU 70, the flash memory 71 can be used as a ROM for storing firmware or the like for the CPU 70. Since the operating speed of the flash memory 71 is fast, the CPU 70 can read data directly without using a RAM or the like, which makes a RAM unnecessary and therefore improves the operating speed of the system LSI. The flash memory 71 can be formed in the same manufacturing processes as those of the flash memory 72 and NAND flash memory 73. For example, the ion implantation process for forming impurity diffused layers and the process of patterning gate electrodes and metal wiring layers can be carried out on three types of flash memories at the same time. In this case, for example, the impurity diffused layers have the same concentration between the individual memories. As described above, since the three flash memories provided in an LSI can be formed in the same processes, the manufacture of LSI can be simplified.

Furthermore, for example, the CPU 70 may be formed on an SOI substrate in the logic circuit area, and each of the memories 71 to 73 may be formed on a bulk silicon substrate in the memory area.

Hereinafter, a nonvolatile semiconductor memory device according to a fifth embodiment of the present invention will be explained. The fifth embodiment is such that a flash memory according to each of the first to third embodiments is used in several applications.

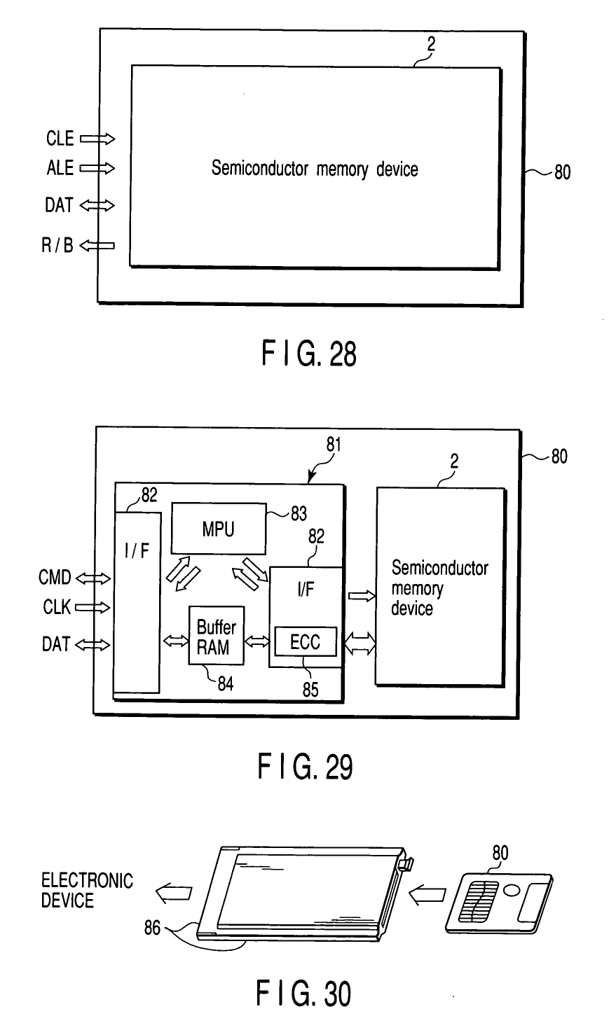

FIG. 28 is a block diagram of a memory card according to the fifth embodiment. As shown in FIG. 28, a memory card 80 has a flash memory 2 according to each of the first to third embodiments. The flash memory 2 receives specific control signals and data from an external unit (not shown). The flash memory 2 also outputs specific control signals and data to the external unit. The flash memory 2 embedded in the memory card 80 is connected to a signal line (DAT) for transferring data, addresses, or commands, a command line enable signal line (CLE) for indicating that a command is being transferred to the signal line DAT, an address line enable signal line (ALE) for indicating that an address is being transferred to the signal line DAT, and a ready/busy signal line (R/B) for indicating whether the flash memory 2 can be operated.

FIG. 29 is a block diagram of another memory card. The memory card of FIG. 29 differs from that of FIG. 28 in that it has a controller 81 that controls the flash memory 2 to exchange specific signals with an external unit (not shown). The controller 81 includes an interface section (I/F) 82 that receives specific signals from the flash memory 2 and the external unit or outputs a specific signal to the external unit, a microprocessor section (MPU) 83 that does calculations to convert a logical address input from the external unit into a physical address, a buffer RAM 84 that stores data temporarily, and an error correcting circuit (ECC) 85 that creates an error correction code. Further the memory card 80 is connected to a command signal line (CMD), a clock signal line (CLK), and a signal line (DAT).

In the memory card 80, the number of control signal lines, the bit width of a signal line, or the configuration of the controller may be modified variously.

As shown in FIG. 30, the memory card 80 is inserted into a card holder 86, which is then connected to electronic equipment (not shown). The card holder 86 may have a part of the function of the controller 81.

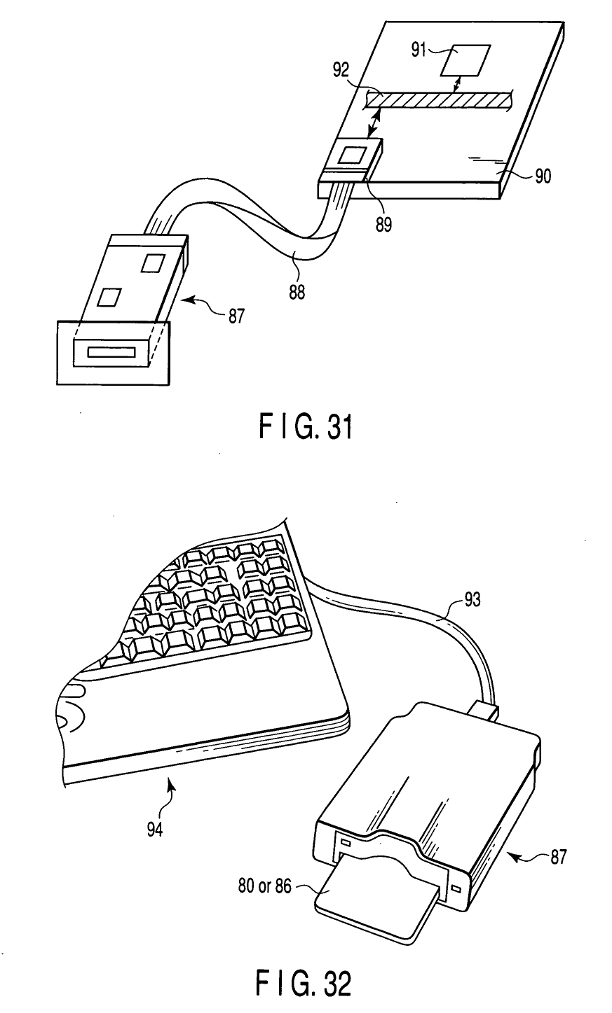

FIG. 31 shows another application. As shown in FIG. 31, the memory card 80, or the card holder 86 into which the memory card 80 has been inserted is inserted into a connection unit 87. The connection unit 87 is connected to a board 90 via a connection line 88 and an interface circuit 89. A CPU 91 and a bus 92 are embedded in the board 90.

FIG. 32 shows another application. The memory card 80, or the card holder 86 into which the memory card 80 has been inserted is inserted into a connection unit 87. The connection unit 87 is connected to a personal computer (PC) 94 via a connection line 93.

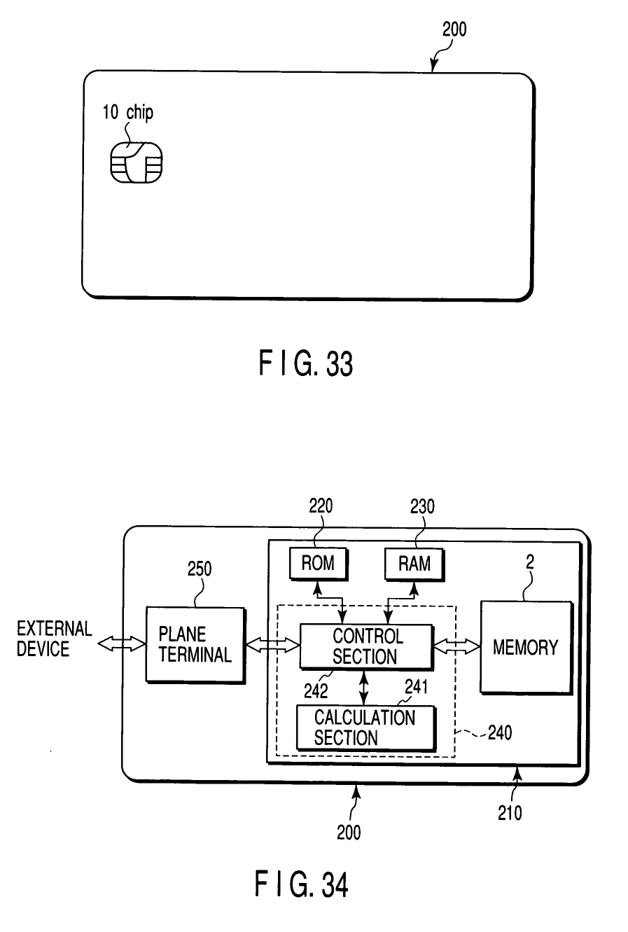

FIGS. 33 and 34 show another application. As shown in FIGS. 33 and 34, an MPU 210 is embedded in an IC card 200. The MPU 210 includes a semiconductor memory device 2 according to each of the first to third embodiments and other circuits including, for example, a ROM 220, a RAM 230, and a CPU 240. The external equipment can be connected to the MPU 210 embedded in the IC card 200 a plane terminal 250 provided on the IC card. The CPU 240 includes a calculation section 241 and a control section 242 connected to the flash memory 2, ROM 220, and RAM 230. For example, the MPU 210 is provided on one side of the IC card 200 and the plane terminal 250 is provided on the other side.

The flash memories explained in the fifth embodiment can be applied not only to a single memory array but also to a semiconductor device having a more complicated logic circuit and the ROM formed on a single semiconductor substrate.

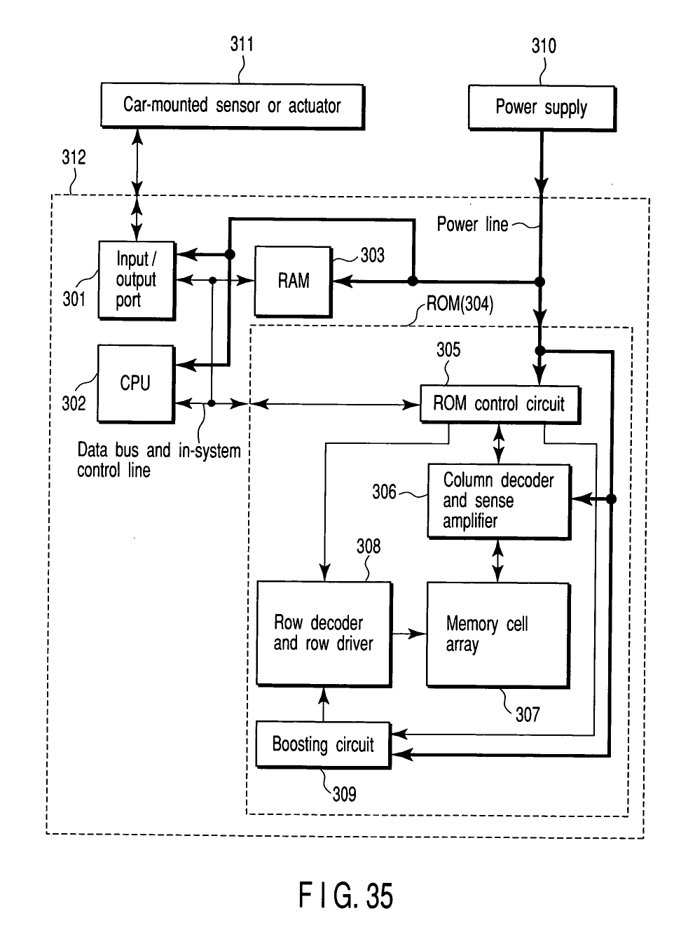

FIG. 35 is a block diagram of a car-mounted system using a flash memory explained in the above embodiments.

As shown in FIG. 35, a car-mounted computer system 312 is connected to a car-mounted sensor and an actuator 311 via an input/output port 301 by wires and exchanges electric signal with the sensor and actuator 311. A power supply 310 supplies electric power to the computer system 312 through a power line. It is desirable that the output of the power supply 310 should be in the range from 1V or higher to 5V or lower, since the voltage range of the output fulfils the power supply voltage specification for the logic circuit of the input/output port 301 and enables a single power supply line to supply power to each circuit and therefore the wiring area to be reduced. In FIG. 35, the power lines are represented by thick lines so that they can be distinguished easily.

The computer system includes the input/output port 301, a RAM 303 acting as a primary storage unit, a CPU (Central Processing Unit) 302 that perform operation on information, and a ROM 304. The computer system exchanges with these units via data bus lines and in-system control lines. The ROM 304 is an area for storing a program executed by the CPU 302 and information about, for example, car numbers and car export destinations. The ROM 304 further has a ROM control circuit 305. The ROM control circuit 305 is a logic circuit that carries out the operation of reading, writing, or erasing a specific address of a memory cell according to the instruction to read, write, or erase data from, into, or from the ROM 304 given through the data bus or in-system control line. In addition, the ROM control circuit 305, which is connected to a column decoder and sense amplifier 306, decodes the address of the specified column and exchanges the writing data or reading data in the column with the column decoder and sense amplifier 306. The column decoder and sense amplifier 306 is connected to a memory cell array 307 via the corresponding data transfer lines. The memory cell array 307 corresponds to the memory cell array 10 explained in each of the first to fifth embodiment. The ROM control circuit 305 is a circuit which is connected to a row decoder and row driver 308 and which decodes the address of the specified row and applies, for example, a boosting voltage supplied in a write operation from a boosting circuit 309 to the data select line corresponding to the row. The boosting circuit 309 is a circuit which has, for example, a charge pump circuit and applies a high voltage ranging from, for example, the power supply voltage or higher to 30V or lower to the memory cell array 307.

The row decoder and row driver 308 is connected to the memory cell array 307 via the corresponding data select lines.

As described above, with the nonvolatile semiconductor memory device according to each of the first to fifth embodiments, in each memory cell of the flash memory, the film thickness of the sidewall insulating film formed on the sidewall of the stacked gate is made greater than ½ of the greatest distance between stacked gates. As a result, the region between the stacked gates is filled completely with the sidewall insulating film. Accordingly, in the SALICIDE process after the formation of the sidewall insulating film, a silicide layer is prevented from being formed in the region between the stacked gates. As a result, the reliability of the operation of the flash memory can be improved.

While in the above embodiments, a stitch region SA1 is provided every eight columns of memory cells (NAND cells), the above embodiments are not limited to this. For instance, a stitch region SA1 may be provided according to the reading speed required in such a manner that it is provided every 64 columns of memory cells, 128 columns of memory cells, or 256 columns of memory cells.

The above embodiments includes:

1. A semiconductor memory device comprising:
a first MOS transistor which has a stacked gate including a first and a second semiconductor layer, and a silicide layer formed in the surface of a source region and on the second semiconductor layer, the second semiconductor layer being formed on the first semiconductor layer with an first inter-gate insulating film interposed therebetween and being connected to the first semiconductor layer electrically;
a second MOS transistor which has a stacked gate including a charge accumulation layer and a control gate formed on the charge accumulation layer with an second inter-gate insulating film interposed therebetween, and a silicide layer formed on the control gate and which is formed adjacent to the first MOS transistor with its source region connected to a drain region of the first MOS transistor;
a third MOS transistor which has a stacked gate including a third and a fourth semiconductor layer, and a silicide layer formed in the surface of a drain region and on the fourth semiconductor layer, the fourth semiconductor layer being formed on the third semiconductor layer with an third inter-gate insulating film interposed therebetween and being connected electrically to the third semiconductor layer, and which is formed adjacent to the second MOS transistor with its source region connected to a drain region of the second MOS transistor; and
a sidewall insulating film which is formed on the sidewalls of the stacked gates of the first to third MOS transistors and which fills a region between the stacked gates of the first and second MOS transistors and a region between the stacked gates of the second and third MOS transistors, no silicide layer being formed in the drain region of the first MOS transistor, in the source and drain regions of the second MOS transistor, and in the source region of the third MOS transistor.

2. The semiconductor memory device according to above structure 1, wherein the entire surface of each of the drain region of the first MOS transistor, the source an d drain regions of the second MOS transistor, and the source region of the third MOS transistor is covered with the sidewall insulating film.

3. The semiconductor memory device according to above structure 1, wherein the surface of a part of each of the source region of the first MOS transistor and the drain region of the third MOS transistor is lower than the surface of the channel region of each of the first and third MOS transistors, and
the surface of each of the drain region of the first MOS transistor, the source and drain regions of the second MOS transistor, and the source region of the third MOS transistor is in the same plane as the surface of the channel region of each of the first to third MOS transistors.

4. The semiconductor memory device according to above structure 1, further comprising:
a memory cell array in which memory cells each including the first to third MOS transistors are arranged in a matrix;
bit lines which each connect the drain regions of the third MOS transistors of the memory cells in a same column commonly;
word lines which are each formed by connecting the control gates of the second MOS transistors of the memory cells in a same row commonly;
first select gate lines which are each formed by connecting the second semiconductor layers of the first MOS transistors of the memory cells in a same row commonly;
second select gate lines which are each formed by connecting the fourth semiconductor layers of the third MOS transistors of the memory cells in a same row commonly;
source lines which connect the source regions of the first MOS transistors commonly;
a column decoder which selects any one of the bit lines;
a first row decoder which selects any one of the word lines; and
a second row decoder which selects any one of the first select gate lines and any one of the second select gate lines.

5. The semiconductor memory device according to above structure 1, further comprising:
a logic circuit which is formed on the semiconductor substrate and which includes a fourth MOS transistor including a gate electrode with a single-layer gate structure and a source and a drain region with a silicide layer on the surface of each of the regions, and the sidewall insulating film formed on the sidewall of the single-layer gate of the fourth MOS transistor.

6. A semiconductor memory device comprising:
a first MOS transistor which has a stacked gate including a first and a second semiconductor layer, and a silicide layer formed in the surface of a drain region and on the second semiconductor layer, the second semiconductor layer being formed on the first semiconductor layer with an first inter-gate insulating film interposed therebetween and being connected to the first semiconductor layer electrically;
a second MOS transistor which has a stacked gate including a third and a fourth semiconductor layer, and a silicide layer formed in the surface of a source region and on the fourth semiconductor layer, the fourth semiconductor layer being formed on the third semiconductor layer with an second inter-gate insulating film interposed therebetween and being connected to the third semiconductor layer electrically;
third MOS transistors which each has a stacked gate including a charge accumulation layer and a control gate formed on the charge accumulation layer with an third inter-gate insulating film interposed therebetween, and a silicide layer formed on the control gate and which are connected in series between the source region of the first MOS transistor and the drain region of the second MOS transistor; and
a sidewall insulating film which is formed on the sidewalls of the stacked gates of the first to third MOS transistors and which fills a region between the stacked gates of the third MOS transistors adjacent to each other, a region between the stacked gates of the first and third MOS transistors, and a region between the stacked gates of the second and third MOS transistors, no silicide layer being formed in the source region of the first MOS transistor, in the drain region of the second MOS transistor, and in the source and drain regions of the third MOS transistor.

7. The semiconductor memory device according to above structure 6, wherein the entire surface of each of the source region of the first MOS transistor, the drain region of the second MOS transistor, and the source and drain regions of the third MOS transistor is covered with the sidewall insulating film.

8. The semiconductor memory device according to above structure 6, wherein the surface of a part of each of the drain region of the first MOS transistor and the source region of the second MOS transistor is lower than the surface of the channel region of each of the first and second MOS transistors, and
the surface of each of the source region of the first MOS transistor, the drain region of the second MOS transistor, and the source and drain regions of the third MOS transistor is in the same plane as the surface of the channel region of each of the first to third MOS transistors.

9. The semiconductor memory device according to above structure 6, further comprising:
a memory cell array in which NAND memory cells each including the first to third MOS transistors are arranged in a matrix;
bit lines which each connect the drain regions of the first MOS transistors of the memory cells in a same column commonly;
word lines which are each formed by connecting the control gates of the third MOS transistors of the memory cells in a same row commonly;
first select gate lines which are each formed by connecting the second semiconductor layers of the first MOS transistors of the memory cells in a same row commonly;
second select gate lines which are each formed by connecting the fourth semiconductor layers of the second MOS transistors of the memory cells in a same row commonly;
source lines which connect the source regions of the second MOS transistors commonly;
a column decoder which selects any one of the bit lines;
a first row decoder which selects any one of the word lines; and
a second row decoder which selects any one of the first select gate lines and any one of the second select gate lines.

10. The semiconductor memory device according to above structure 6, further comprising:
a logic circuit which is formed on the semiconductor substrate and which includes a fourth MOS transistor including a gate electrode with a single-layer gate structure and a source and a drain region with a silicide layer on the surface of each of the regions, and the sidewall insulating film formed on the sidewall of the single-layer gate of the fourth MOS transistor.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor memory device comprising:
a first MOS transistor which has a stacked gate including a first and a second semiconductor layer, and a silicide layer formed in the surface of a source region and on the second semiconductor layer, the second semiconductor layer being formed on the first semiconductor layer with an first inter-gate insulating film interposed therebetween and being connected to the first semiconductor layer electrically;
a second MOS transistor which has a stacked gate including a charge accumulation layer and a control gate formed on the charge accumulation layer with an second inter-gate insulating film interposed therebetween, and a silicide layer formed in the surface of a drain region and on the control gate and which is formed adjacent to the first MOS transistor with its source region connected to a drain region of the first MOS transistor; and
a sidewall insulating film which is formed on the sidewall of the stacked gate of the first MOS transistor, the film thickness of the sidewall insulating film formed on the sidewall facing the source region at the stacked gate of the first MOS transistor being greater than ½ of the distance between the stacked gates of the first and second MOS transistors, and no silicide layer being formed in the drain region of the first MOS transistor and in the source region of the second MOS transistor.

2. The semiconductor memory device according to claim 1, wherein the surface of a part of each of the source region of the first MOS transistor and the drain region of the second MOS transistor is lower than the surface of the channel region of each of the first and second MOS transistors, and
the surface of each of the drain region of the first MOS transistor and the source region of the second MOS transistor is in the same plane as the surface of the channel region of each of the first and second MOS transistors.

3. The semiconductor memory device according to claim 1, further comprising:
a memory cell array in which memory cells each including the first and second MOS transistors are arranged in a matrix;
bit lines which each connect the drain regions of the second MOS transistors of the memory cells in a same column commonly;
word lines which are each formed by connecting the control gates of the second MOS transistors of the memory cells in a same row commonly;
select gate lines which are each formed by connecting the second semiconductor layers of the first MOS transistors of the memory cells in a same row commonly;
source lines which connect the source regions of the first MOS transistors commonly;
a column decoder which selects any one of the bit lines;
a first row decoder which selects any one of the word lines; and
a second row decoder which selects any one of the select gate lines.

4. The semiconductor memory device according to claim 1, further comprising:
a logic circuit which is formed on the semiconductor substrate and which includes a third MOS transistor including a gate electrode with a single-layer gate structure and a source and a drain region with a silicide layer in the surface of each of the regions, and the sidewall insulating film formed on the sidewall of the single-layer gate of the third MOS transistor.

5. A semiconductor memory device comprising:
a first MOS transistor which has a stacked gate including a first and a second semiconductor layer, and a silicide layer formed in the surface of a source region and on the second semiconductor layer, the second semiconductor layer being formed on the first semiconductor layer with an first inter-gate insulating film interposed therebetween and being connected to the first semiconductor layer electrically;
a second MOS transistor which has a stacked gate including a charge accumulation layer and a control gate formed on the charge accumulation layer with an second inter-gate insulating film interposed therebetween, and a silicide layer formed in the surface of a drain region and on the control gate and which is formed adjacent to the first MOS transistor with its source region connected to a drain region of the first MOS transistor; and
a sidewall insulating film which is formed on the sidewalls of the stacked gates of the first and second MOS transistors and which fills a region between the stacked gates of the first and second MOS transistors, no silicide layer being formed in the drain region of the first MOS transistor and in the source region of the second MOS transistor.

6. The semiconductor memory device according to claim 5, wherein the entire surface of each of the drain region of the first MOS transistor and the source region of the second MOS transistor is covered with the sidewall insulating film.

7. The semiconductor memory device according to claim 5, wherein the surface of a part of each of the source region of the first MOS transistor and the drain region of the second MOS transistor is lower than the surface of the channel region of each of the first and second MOS transistors, and
the surface of each of the drain region of the first MOS transistor and the source region of the second MOS transistor is in the same plane as the surface of the channel region of each of the first and second MOS transistors.

8. The semiconductor memory device according to claim 5, further comprising:
a memory cell array in which memory cells each including the first and second MOS transistors are arranged in a matrix;
bit lines which each connect the drain regions of the second MOS transistors of the memory cells in a same column commonly;
word lines which are each formed by connecting the control gates of the MOS transistors of the memory cells in a same row commonly;
select gate lines which are each formed by connecting the second semiconductor layers of the first MOS transistors of the memory cells in a same row commonly;
source lines which connect the source regions of the first MOS transistors commonly;
a column decoder which selects any one of the bit lines;
a first row decoder which selects any one of the word lines; and
a second row decoder which selects any one of the select gate lines.

9. The semiconductor memory device according to claim 5, further comprising:
a logic circuit which is formed on the semiconductor substrate and which includes a third MOS transistor including a gate electrode with a single-layer gate structure and a source and a drain region with a silicide layer in the surface of each of the regions, and the sidewall insulating film formed on the sidewall of the single-layer gate of the third MOS transistor.

10. A semiconductor memory device comprising:
a first MOS transistor which has a stacked gate including a first and a second semiconductor layer, and a silicide layer formed in the surface of a source region and on the second semiconductor layer, the second semiconductor layer being formed on the first semiconductor layer with an first inter-gate insulating film interposed therebetween and being connected to the first semiconductor layer electrically;
a second MOS transistor which has a stacked gate including a charge accumulation layer and a control gate formed on the charge accumulation layer with an second inter-gate insulating film interposed therebetween, and a silicide layer formed on the control gate and which is formed adjacent to the first MOS transistor with its source region connected to the drain region of the first MOS transistor;
a third MOS transistor which has a stacked gate including a third and a fourth semiconductor layer, and a silicide layer formed in the surface of a drain region and on the fourth semiconductor layer, the fourth semiconductor layer being formed on the third semiconductor layer with an third inter-gate insulating film interposed therebetween and being connected electrically to the third semiconductor layer and which is formed adjacent to the second MOS transistor with its source region connected to the drain region of the second MOS transistor; and
a sidewall insulating film which is formed on the sidewalls of the stacked gates of the first and third MOS transistors, the film thickness of the sidewall insulating film formed on the sidewall facing the source region at the stacked gate of the first MOS transistor and the film thickness of the sidewall insulating film formed on the sidewall facing the drain region at the stacked gate of the third MOS transistor being greater than ½ of the distance between the stacked gates of the second and third MOS transistors and greater than ½ of the distance between the stacked gates of the first and second MOS transistors, and no silicide layer being formed in the drain region of the first MOS transistor, in the source and drain regions of the second MOS transistor, and in the source region of the third MOS transistor.

11. The semiconductor memory device according to claim 10, wherein the surface of a part of each of the source region of the first MOS transistor and the drain region of the third MOS transistor is lower than the surface of the channel region of each of the first and third MOS transistors, and
the surface of each of the drain region of the first MOS transistor, the source and drain regions of the second MOS transistor, and the source region of the third MOS transistor is in the same plane as the surface of the channel region of each of the first to third MOS transistors.

12. The semiconductor memory device according to claim 10, further comprising:
a memory cell array in which memory cells each including the first to third MOS transistors are arranged in a matrix;
bit lines which each connect the drain regions of the third MOS transistors of the memory cells in a same column commonly;
word lines which are each formed by connecting the control gates of the second MOS transistors of the memory cells in a same row commonly;
first select gate lines which are each formed by connecting the second semiconductor layers of the first MOS transistors of the memory cells in a same row commonly;
second select gate lines which are each formed by connecting the fourth semiconductor layers of the third MOS transistors of the memory cells in a same row commonly;
source lines which connect the source regions of the first MOS transistors commonly;
a column decoder which selects any one of the bit lines;
a first row decoder which selects any one of the word lines; and
a second row decoder which selects any one of the first select gate lines and any one of the second select gate lines.

13. The semiconductor memory device according to claim 10, further comprising:
a logic circuit which is formed on the semiconductor substrate and which includes a fourth MOS transistor including a gate electrode with a single-layer gate structure and a source and a drain region with a silicide layer in the surface of each of the regions, and the sidewall insulating film formed on the sidewall of the single-layer gate of the fourth MOS transistor.

14. A semiconductor memory device comprising:
a first MOS transistor which has a stacked gate including a first and a second semiconductor layer, and a silicide layer formed in the surface of a drain region and on the second semiconductor layer, the second semiconductor layer being formed on the first semiconductor layer with an first inter-gate insulating film interposed therebetween and being connected to the first semiconductor layer electrically;
a second MOS transistor which has a stacked gate including a third and a fourth semiconductor layer, and a silicide layer formed in the surface of a source region and on the fourth semiconductor layer, the fourth semiconductor layer being formed on the third semiconductor layer with an second inter-gate insulating film interposed therebetween and being connected to the third semiconductor layer electrically;
third MOS transistors which each has a stacked gate including a charge accumulation layer and a control gate formed on the charge accumulation layer with an third inter-gate insulating film interposed therebetween, and a silicide layer formed on the control gate and which are connected in series between the source region of the first MOS transistor and the drain region of the second MOS transistor; and
a sidewall insulating film which is formed on the sidewalls of the stacked gates of the first and second MOS transistors, the film thickness of the sidewall insulating film formed on the sidewall facing the drain region at the stacked gate of the first MOS transistor and the film thickness of the sidewall insulating film formed on the sidewall facing the source region at the stacked gate of the second MOS transistor being greater than ½ of the distance between the stacked gates of the third MOS transistors adjacent to each other, greater than ½ of the distance between the stacked gates of the first and third MOS transistors, and greater than ½ of the distance between the stacked gates of the second and third MOS transistors, and no silicide layer being formed in the source region of the first MOS transistor, in the drain region of the second MOS transistor, and in the source and drain regions of the third MOS transistor.

15. The semiconductor memory device according to claim 14, wherein the surface of a part of each of the drain region of the first MOS transistor and the source region of the second MOS transistor is lower than the surface of the channel region of each of the first and second MOS transistors, and
the surface of each of the source region of the first MOS transistor, the drain region of the second MOS transistor, and the source and drain regions of the third MOS transistor is in the same plane as the surface of the channel region of each of the first to third MOS transistors.

16. The semiconductor memory device according to claim 14, further comprising:
a memory cell array in which NAND memory cells each including the first to third MOS transistors are arranged in a matrix;
bit lines which each connect the drain regions of the first MOS transistors of the memory cells in a same column commonly;
word lines which are each formed by connecting the control gates of the third MOS transistors of the memory cells in a same row commonly;
first select gate lines which are each formed by connecting the second semiconductor layers of the first MOS transistors of the memory cells in a same row commonly;
second select gate lines which are each formed by connecting the fourth semiconductor layers of the second MOS transistors of the memory cells in a same row commonly;
source lines which connect the source regions of the second MOS transistors commonly;
a column decoder which selects any one of the bit lines;
a first row decoder which selects any one of the word lines; and
a second row decoder which selects any one of the first select gate lines and any one of the second select gate lines.

17. The semiconductor memory device according to claim 14, further comprising:
a logic circuit which is formed on the semiconductor substrate and which includes a fourth MOS transistor including a gate electrode with a single-layer gate structure and a source and a drain region with a silicide layer in the surface of each of the regions, and the sidewall insulating film formed on the sidewall of the single-layer gate of the fourth MOS transistor.
